(19) United States
(12) Patent Application Publication
(10) Pub. No.: US 2025/0380597 A1
(43) Pub. Date: Dec. 11, 2025

(54) LIGHT-EMITTING DEVICE AND APPARATUS INCLUDING THE SAME

(71) Applicant: CANON KABUSHIKI KAISHA, Tokyo (JP)

(72) Inventors: KOSUKE TANAKA, Kanagawa (JP); MASAHIKO KONDO, Kanagawa (JP)

(21) Appl. No.: 19/228,413

(22) Filed: Jun. 4, 2025

(30) Foreign Application Priority Data
Jun. 10, 2024 (JP) 2024-093864

(51) Int. Cl. H10K 59/80

(52) U.S. Cl. CPC H10K 59/873

(57) ABSTRACT

A light-emitting device includes a light-emitting area including a plurality of light-emitting elements arranged on a surface of a substrate; a moisture-resistant ring arranged on the surface to surround the light-emitting area; and an insulating layer covering the light-emitting area and the moisture-resistant ring, wherein in an orthogonal projection to the surface, the insulating layer has a shape obtained by merging a first portion having a plurality of corners including a first corner and a second portion having a shape with the first corner expanded in an outward direction.

### BACKGROUND

### Field of the Technology

The present disclosure relates to a light-emitting device and an apparatus including the same.

### Description of the Related Art

Japanese Patent Laid-Open No. 2018-29070 describes that a guard ring is provided in a light-emitting device to prevent, when cutting an original substrate to obtain a plurality of light-emitting devices, the influences of the impact and static electricity from spreading to the drive circuit or pixels of the light-emitting device, and to prevent moisture from entering the light-emitting device from its end face. This guard ring can also be called a moisture-resistant ring.

The moisture-resistant ring is covered with an insulating layer to improve the moisture-resistance performance. Since such an insulating layer interferes with dicing of the substrate, the insulating layer in the scribe area can be removed in an etching step before dicing. The etching step can be performed through the opening of a photoresist pattern formed by a photolithography step. If the corner of the opening of the photoresist pattern is rounded or a slight alignment error occurs due to a failure in the photolithography step, the corner of the moisture-resistant ring is exposed, and accordingly the corner of the moisture-resistance ring can be removed during the etching step. In such a case, the moisture-resistance performance of the light-emitting device can be degraded.

### SUMMARY

The present disclosure provides a technique advantageous in improving the moisture-resistance performance of a light-emitting device.

According to some embodiments, a light-emitting device includes a light-emitting area including a plurality of light-emitting elements arranged on a surface of a substrate; a moisture-resistant ring arranged on the surface to surround the light-emitting area; and an insulating layer covering the light-emitting area and the moisture-resistant ring, wherein in an orthogonal projection to the surface, the insulating layer has a shape obtained by merging a first portion having a plurality of corners including a first corner and a second portion having a shape with the first corner expanded in an outward direction.

Features of the present disclosure will become apparent from the following description of embodiments with reference to the attached drawings. The following description of embodiments are described by way of example.

### BRIEF DESCRIPTION OF THE DRAWINGS

FIG. 1 is a plan view schematically showing the arrangement of a light-emitting device according to the first embodiment.

FIGS. 2A to 2C are views for explaining the shape of an insulating layer covering a light-emitting area and a moisture-resistant ring.

FIG. 3A is a plan view showing the first modification of the light-emitting device according to the first embodiment.

FIG. 3B is a plan view showing the second modification of the light-emitting device according to the first embodiment.

FIG. 3C is a plan view showing the third modification of the light-emitting device according to the first embodiment.

FIG. 4 is a schematic sectional view showing an example of the arrangement of the light-emitting device taken along a cut line A in FIG. 1.

FIG. 5 is an enlarged view schematically showing an example of the arrangement of the light-emitting device in a cut area B in FIG. 1.

FIG. 6A is a plan view showing a modification of the shape of the insulating layer at the corner of the moisture-resistant ring.

FIG. 6B is a plan view showing another modification of the shape of the insulating layer at the corner of the moisture-resistant ring.

FIG. 7 is a plan view schematically showing the arrangement of a light-emitting device according to the second embodiment.

FIG. 8A is an enlarged view of a cut area C in FIG. 7.

FIG. 8B is an enlarged view showing a modification of the arrangement of the cut area C in FIG. 7.

FIG. 9 is a plan view schematically showing the arrangement of an original substrate with a plurality of light-emitting devices arranged thereon in a manufacturing process.

FIG. 10A is a view for explaining the procedure of a process of forming a trench by etching insulating layers arranged in a scribe area.

FIG. 10B is a view for explaining the procedure of the process of forming the trench by etching the insulating layers arranged in the scribe area.

FIG. 10C is a view for explaining the procedure of the process of forming the trench by etching the insulating layers arranged in the scribe area.

FIG. 11 is a schematic view showing the first application example of the light-emitting device according to the embodiment.

FIGS. 12A to 12C are schematic views showing the second application example of the light-emitting device according to the embodiment.

FIGS. 13A and 13B are schematic views showing the third application example of the light-emitting device according to the embodiment.

FIG. 14 is a schematic view showing the fourth application example of the light-emitting device according to the embodiment.

FIG. 15A is a schematic view showing the fifth application example of the light-emitting device according to the embodiment.

FIG. 15B is a schematic view showing the sixth application example of the light-emitting device according to the embodiment.

FIG. 16A is a schematic view showing the seventh application example of the light-emitting device according to the embodiment.

FIG. 16B is a schematic view showing the eighth application example of the light-emitting device according to the embodiment.

FIG. 17A is a schematic view showing the ninth application example of the light-emitting device according to the embodiment.

FIG. 17B is a schematic view showing the tenth application example of the light-emitting device according to the embodiment.

FIG. 18A is a schematic view showing the eleventh application example of the light-emitting device according to the embodiment.

FIG. 18B is a schematic view showing the twelfth application example of the light-emitting device according to the embodiment.

### DESCRIPTION OF THE EMBODIMENTS

Hereinafter, various exemplary embodiments, features, and aspects will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

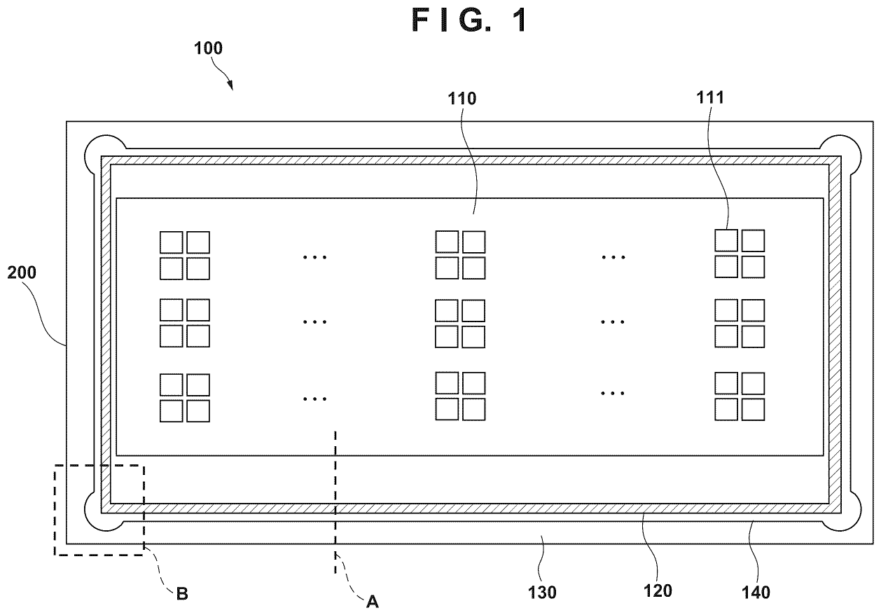

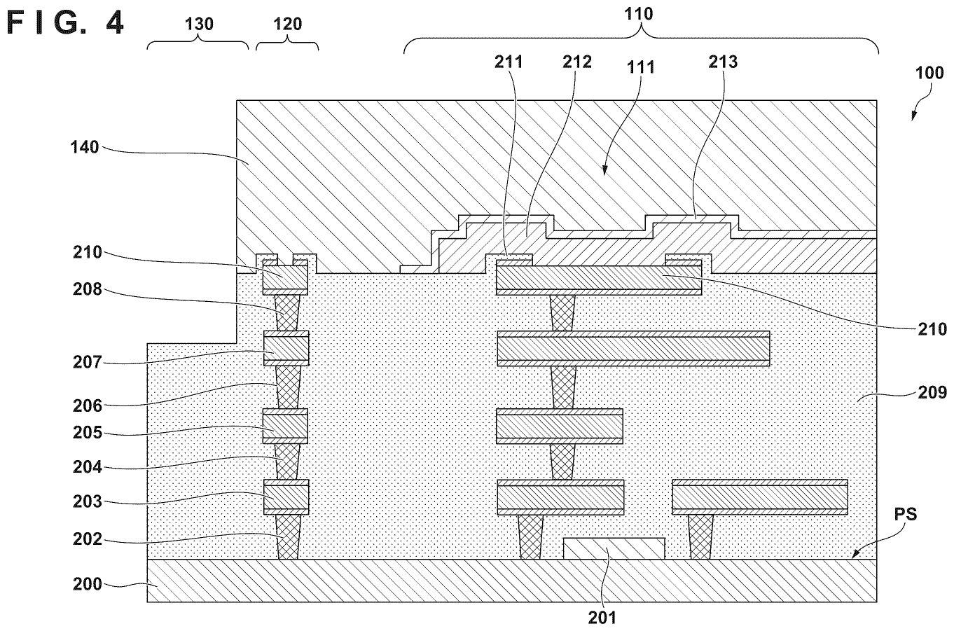

FIG. 1 is a plan view schematically showing the arrangement of a light-emitting device 100 according to the first embodiment. The light-emitting device 100 includes a plurality of light-emitting elements 111 arranged on the surface of a substrate 200. Note that the surface of the substrate 200 is shown as a surface PS in FIG. 4, which will be referred to later. The plurality of light-emitting elements 111 forms a light-emitting area 110. The light-emitting area 110 may be understood as a pixel array. The light-emitting element 111 can be, for example, an organic electroluminescence (EL) light emitting diode (OLED) element. The light-emitting device 100 can also include a moisture-resistant ring 120 arranged on the surface of the substrate 200 to surround the light-emitting area 110. The moisture-resistant ring 120 can have a frame shape that surrounds the whole circumference of the light-emitting area 110.

Before dicing the original substrate on which the plurality of light-emitting devices 100 is formed, the plurality of light-emitting devices 100 is arranged on the original substrate while being separated by a scribe area 130. By cutting the original substrate at the scribe area 130, the plurality of light-emitting devices 100 can be diced, that is, formed into chips. After dicing, a part of the scribe area 130 can remain around the light-emitting device 100. The moisture-resistant ring 120 prevents the influences of the impact and static electricity upon cutting the original substrate from spreading to the light-emitting area 110 and the like, and prevents moisture from entering the light-emitting device 100 from the cut surface of the original substrate (the end face of the light-emitting device 100).

The light-emitting device 100 includes an insulating layer 140 covering the light-emitting area 110 and the moisture-resistant ring 120. The insulating layer 140 can serve as a sealing layer. The insulating layer 140 as the sealing layer suppresses, for example, moisture entering each light-emitting element 111 in the light-emitting area 110. A partial region of the insulating layer 140 in the scribe area 130 has been removed by etching through the opening of a photoresist pattern formed by a photolithography step. In an orthogonal projection to the surface of the substrate 200 (which is also referred to as a planar view or a plan view for the sake of convenience, and FIG. 1 schematically shows the orthogonal projection to the surface of the substrate 200), the outer edge of the insulating layer 140 surrounds the whole circumference of the outer edge of the moisture-resistant ring 120. The outer edge of the insulating layer 140 is arranged while providing a minimum distance equal to or larger than a predetermined distance with respect to the outer edge of the moisture-resistant ring 120. In the orthogonal projection to the surface of the substrate 200, the insulating layer 140 can have a shape obtained by merging the first portion having a plurality of corners and the second portion having a shape with the plurality of corners expanded outward. With this arrangement, the moisture-resistance performance can be ensured.

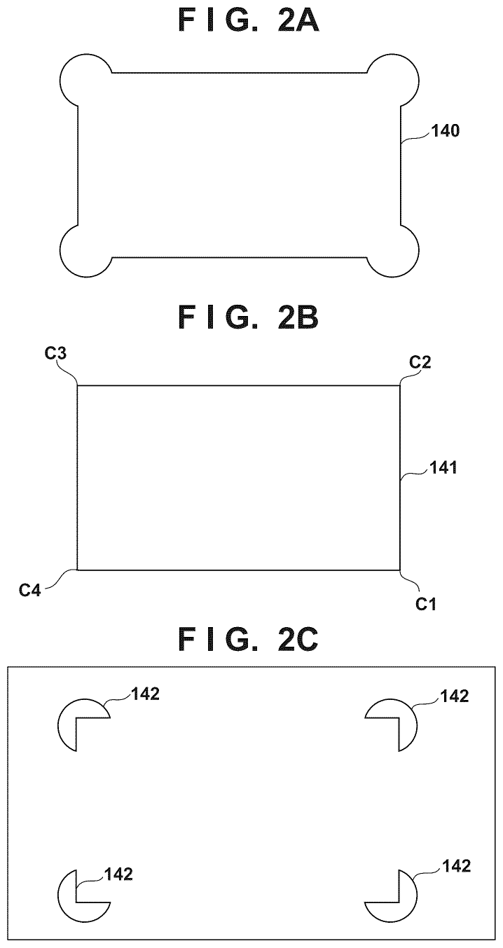

With reference to FIGS. 2A to 2C, the shape of the insulating layer 140 will be described. Note that the shape shown in FIG. 2 is exaggerated for the sake of descriptive convenience. FIG. 2A shows only the insulating layer 140 in FIG. 1. FIG. 2B shows a first portion 141, and FIG. 2C shows a second portion 142. In the orthogonal projection to the surface of the substrate 200, the insulating layer 140 can have a shape obtained by merging the first portion 141 having a plurality of corners C1 to C4 and the second portion 142 having a shape with the plurality of corners C1 to C4 expanded outward. Here, in one aspect, the plurality of corners C1 to C4 includes the first corner (for example, C1), and the second portion 142 has a shape with the first corner expanded outward (outward of the first portion 141). The first portion 141 is a closed shape. The second portion 142 can include a plurality of segments separated from each other. Each segment is a closed shape. The first portion 141 and the second portion 142 are virtual figures for explaining the shape of the insulating layer 140 (the shape of the outer edge). In one aspect, merging the first portion and the second portion means coupling the first portion and the second portion. In another aspect, merging the first portion and the second portion means taking the OR of the first portion and the second portion in the orthogonal projection to the surface of the substrate 200.

From one viewpoint, the second portion 142 can include a portion having a round shape. The portion having the round shape can decide a part of the outer edge of the insulating layer 140. From another viewpoint, the second portion 142 can have a shape with the corner of the first portion 141 expanded in a radial direction. From still another viewpoint, in the orthogonal projection to the surface of the substrate 200, the portion of the outer edge of the insulating layer 140 located outside the corner of the moisture-resistant ring 120 has a shape partially surrounding the corner of the moisture-resistant ring 120.

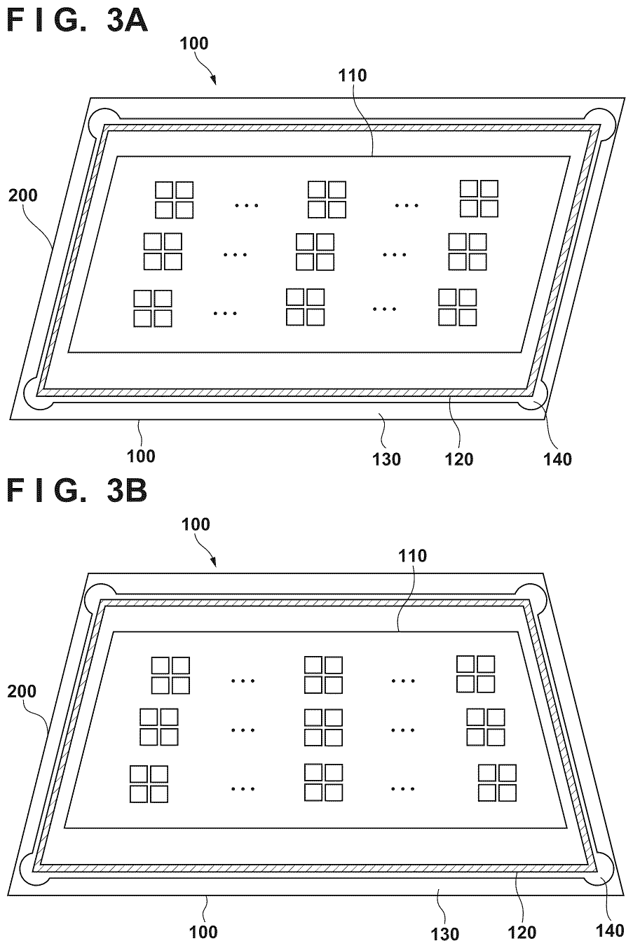

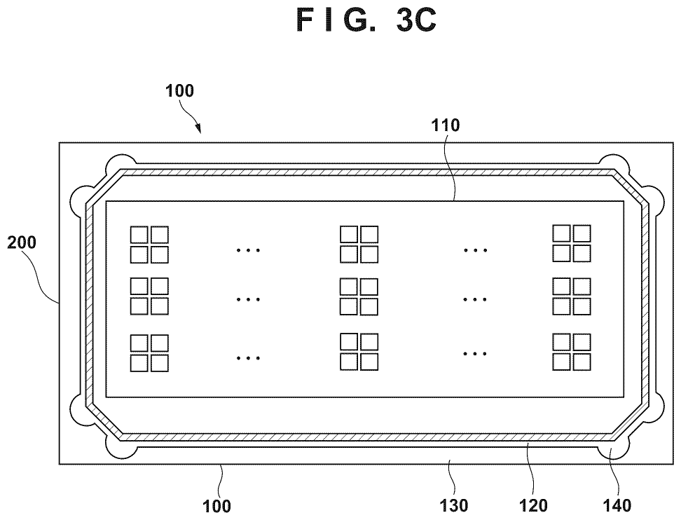

Each of FIGS. 3A to 3C shows a modification of the light-emitting device 100. In each of the modifications shown in FIGS. 3A to 3C, in the orthogonal projection to the surface of the substrate 200, the insulating layer 140 has a shape obtained by merging the first portion having a plurality of corners and the second portion having a shape with each of the plurality of corners expanded outward. From another viewpoint, in each of the modifications shown in FIGS. 3A to 3C, the insulating layer 140 has a shape obtained by merging the first portion having a plurality of corners including the first corner, and the second portion having a shape with the first corner expanded outward. From still another viewpoint, in each of the modifications shown in FIGS. 3A to 3C, the insulating layer 140 has a shape obtained by merging the first portion having a plurality of corners including the first corner and the second corner, and the second portion having a shape with each of the first corner and the second corner expanded outward. Each of the modifications shown in FIGS. 3A to 3C exemplarily shows that the interior angle of two sides forming the first corner as one of the plurality of corners of the first portion can be a right angle, an obtuse angle, or an acute angle. When forming a photoresist pattern used in patterning of the insulating layer 140, a patterning error can occur, such as the rounded corner of the opening of the photoresist pattern or a slight alignment error. However, when the insulating layer 140 has the shape as described above, it is possible to pattern the insulating layer 140 such that the insulating layer 140 covers the corners of the moisture-resistant ring 120. This is advantageous in reducing the exposure of the moisture-resistant ring 120 and suppressing moisture entering the light-emitting area 110.

In the examples shown in FIGS. 1 to 3B, the first portion 141 has a quadrangular shape or a polygonal shape. The quadrangle can be, for example, a rectangle, a parallelogram, or a trapezoid. Here, the concept of a trapezoid includes a parallelogram, and the concept of a parallelogram includes a rectangle. From another viewpoint, in the examples shown in FIGS. 1 to 3B, the first portion 141 has a shape that is mathematically similar to the outer shape of the moisture-resistant ring 120. In still another viewpoint, in the examples shown in FIGS. 1 to 3B, the first portion 141 has a shape that is mathematically similar to the smallest quadrangle that contains the moisture-resistant ring 120. In the example shown in FIG. 3C, the first portion 141 has a polygonal (more specifically, octagonal) shape. In the examples shown in FIGS. 1 to 3C, the first portion 141 has a shape that is mathematically similar to the smallest quadrangle (virtual figure) that contains the moisture-resistant ring 120.

FIG. 4 is a schematic sectional view showing an example of the arrangement of the light-emitting device 100 taken along a cut line A in FIG. 1. FIG. 4 schematically shows the structure including the light-emitting area 110, the moisture-resistant ring 120, and the scribe area 130 together with the substrate 200. FIG. 4 also shows the surface PS of the substrate 200. The substrate 200 may be, for example, a silicon substrate, or may be a substrate made of another material.

In the light-emitting area 110, for example, the plurality of light-emitting elements 111 and a plurality of transistors 201 configured to drive or control them are arranged. The light-emitting element 111 can include, for example, a lower electrode 210, an organic layer 212 including a light-emitting layer, and an upper electrode 213. The light-emitting device 100 can also include, for example, wiring layers 203, 205, and 207, and plugs 204, 206, and 208 for connecting the wiring layers to each other. The light-emitting device 100 can also include a plug 202 for connecting the wiring layer and the transistor 201 or the substrate 200. The wiring layers 203, 205, and 207 and the plugs 202, 204, 206, and 208 are arranged in an insulating layer 209. The wiring layers 203, 205, and 207, the plugs 202, 204, 206, and 208, and the lower electrode 210 arranged in the region of the light-emitting area 110 can have substantially the same film structure and film thickness as those arranged in the region of the moisture-resistant ring 120, respectively. Note that each element constituting the moisture-resistant ring 120 may be omitted, as appropriate. For example, the wiring layer 205 may be omitted and the wiring layer 203 and the wiring layer 207 may be directly connected. The substrate 200 is a single-crystal silicon layer having a thickness of, for example, 750 to 800 micrometer (μm), and preferably 770 to 780 μm.

The organic layer 212 is arranged between the upper electrode 213 and the lower electrode 210. The lower electrode 210 is connected to the wiring layer 207 via the plug 208. The insulating layer 140 for ensuring the moisture resistance is arranged above the organic layer 212. The material for the insulating layer 140 can be arbitrarily selected from materials that are generally used in semiconductor apparatuses. The insulating layer 140 can be formed from, for example, a silicon nitride film which is a dense film with optical transparency. The insulating layer 140 may have a stacked structure. For example, the insulating layer 140 can have a three-layer structure including a silicon nitride film formed by a plasma chemical vapor deposition (CVD) method, an alumina film (Al₂O₃) formed by an atomic layer deposition (ALD) method, and a silicon nitride film formed by a plasma CVD method. The transistor 201 can be formed by a known semiconductor process technique. The contact plug 202 can be formed of a high melting metal (refractory metal) such as tungsten. The wiring layers 203, 205, and 207 can be formed of aluminum or copper. The insulating layer 209 can be formed from a silicon-based insulating layer made of a silicon oxide film, a silicon nitride film, or a silicon carbide film. The insulating layer 209 may contain a Low-k material having a low dielectric constant, or the like.

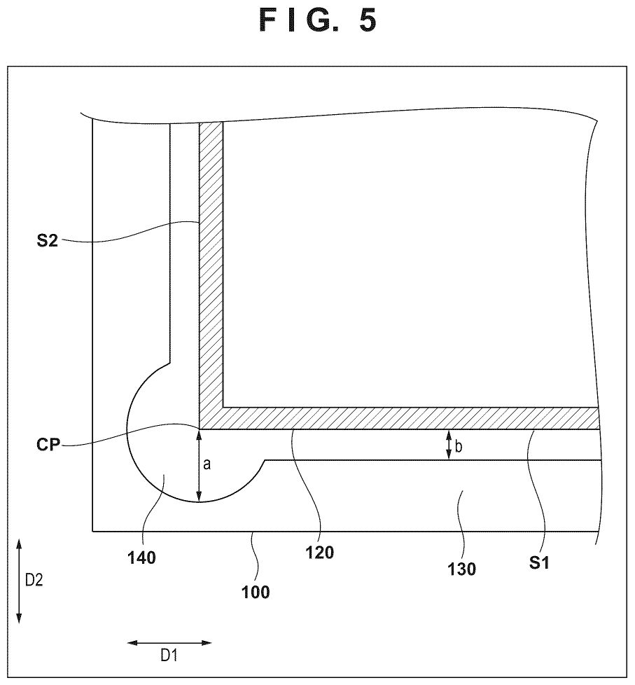

FIG. 5 is an enlarged view schematically showing an example of the arrangement of the light-emitting device 100 in a cut area B in FIG. 1. The moisture-resistant ring 120 has a first side S1 extending in a first direction D1, a second side S2 extending in a second direction D2 different from the first direction D1, and a corner CP between the first side S1 and the second side S2. The insulating layer 140 can have a shape obtained by expanding the portion located outside the corner CP of the moisture-resistant ring 120 in an outward direction (in the outward direction of the moisture-resistant ring 120). The outer edge of the shape can include, for example, a circular arc. The angle of the corner CP of the moisture-resistant ring 120 can be an arbitrary angle such as a right angle, an obtuse angle, or an acute angle. In one aspect, a shortest distance a from the corner CP of the moisture-resistant ring 120 to the outer edge of the insulating layer 140 is preferably larger than a shortest distance b from the first side S1 of the moisture-resistant ring 120 to the outer edge of the insulating layer 140. When forming a photoresist pattern used in patterning of the insulating layer 140, a patterning error can occur, such as the rounded corner of the opening of the photoresist pattern or a slight alignment error. However, the arrangement satisfying a>b is advantageous for patterning the insulating layer 140 such that the insulating layer 140 covers the corner CP of the moisture-resistant ring 120. This is advantageous in preventing exposure of the moisture-resistant ring 120 and suppressing moisture entering the light-emitting area 110.

As exemplarily shown in FIGS. 1 to 3C, in the orthogonal projection to the surface of the substrate 200. the outer edge of the moisture-resistant ring 120 can have a shape having a plurality of vertices and a plurality of sides connecting adjacent vertices among the plurality of vertices. The arrangement exemplarily shown in FIG. 5 can be applied not only to one vertex but also to other vertices. That is, in the orthogonal projection to the surface of the substrate 200, the shortest distance from each vertex of the outer edge of the moisture-resistant ring 120 to the outer edge of the insulating layer 140 is preferably larger than the shortest distance from each side of the outer edge of the moisture-resistant ring 120 to the outer edge of the insulating layer 140. From another viewpoint, the outer edge of the insulating layer 140 has a shape obtained by expanding, in an outward direction, the corner in a shape that is mathematically similar to a polygon that contains the moisture-resistant ring 120.

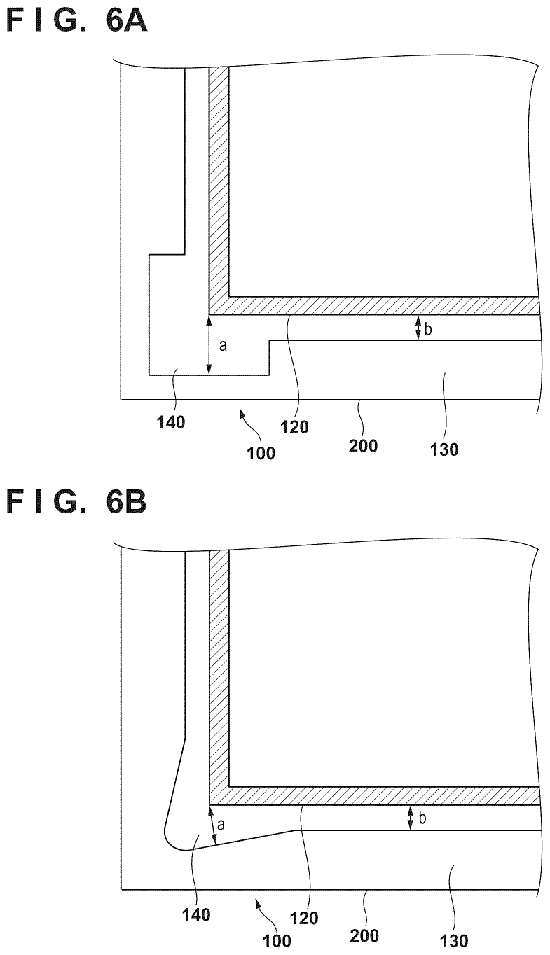

Each of FIGS. 6A and 6B shows a modification of the shape of the insulating layer 140 at the corner of the moisture-resistant ring 120. In each of the examples shown in FIGS. 1 to 5, the insulating layer 140 has a shape obtained by expanding the corner of the moisture-resistant ring 120, and the shape has a round shape or a circular arc. On the other hand, in the example shown in FIG. 6A, the insulating layer 140 has a shape obtained by expanding the corner of the moisture-resistant ring 120, and the shape has four sides of a quadrangle. In the example shown in FIG. 6B, the insulating layer 140 has a shape obtained by expanding the corner of the moisture-resistant ring 120, and the shape has two sides of a triangle.

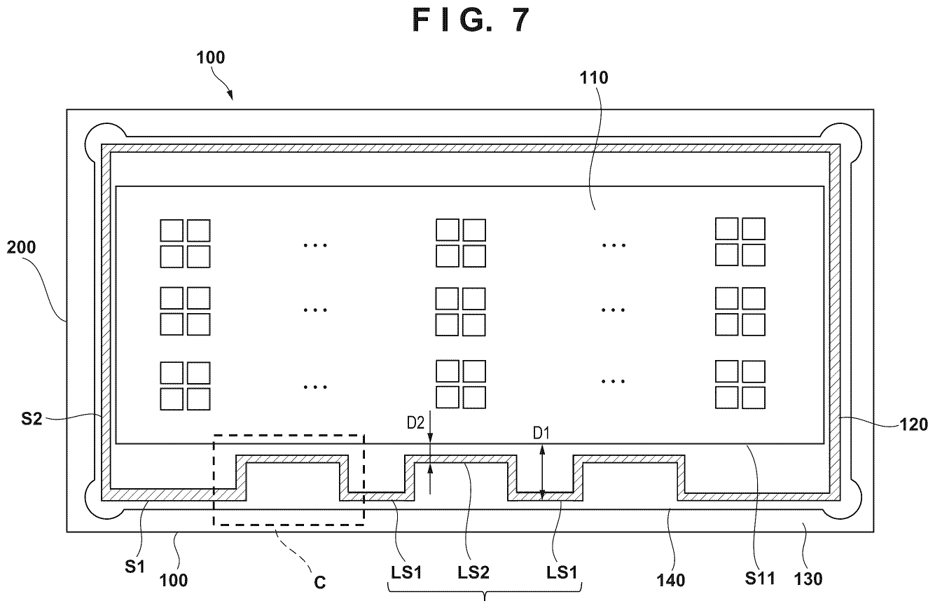

FIG. 7 is a plan view schematically showing the arrangement of a light-emitting device 100 according to the second embodiment. Matters not mentioned for the light-emitting device 100 according to the second embodiment can follow the first embodiment. The outer shape of a light-emitting area 110 is a polygon, for example, a quadrangle. The outer shape of a moisture-resistant ring 120 includes a portion PP along one side S11 of the polygon forming the outer shape of the light-emitting area 110. The portion PP has two first line segments LS1 whose distance from the one side S11 is a first distance D1, and a second line segment LS2 whose distance D2 from the one side S11 is smaller than the first distance DI and which is located between the two first line segments LS1. It may be understood that the shape of the portion PP is a shape including a concave portion in the orthogonal projection to the surface of the substrate 200.

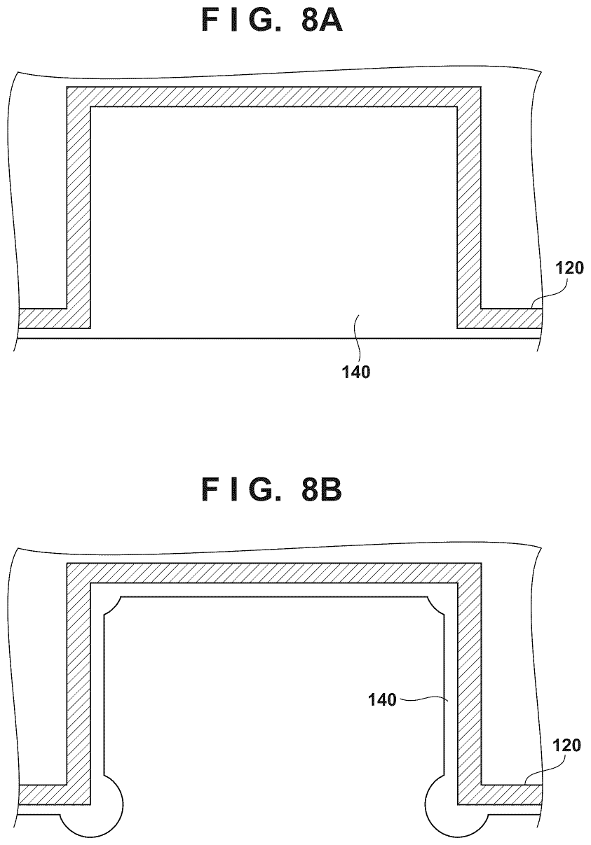

Also in the light-emitting device 100 according to the second embodiment exemplarily shown in FIG. 7, the first portion that virtually defines the shape of the outer edge of an insulating layer 140 can have a shape that is mathematically similar to the smallest quadrangle that contains the moisture-resistant ring. FIG. 8A is an enlarged view of a cut area C in FIG. 7. In the example shown in FIG. 8A, the first portion that virtually defines the shape of the outer edge of the insulating layer 140 has a shape that is mathematically similar to the smallest quadrangle that contains the moisture-resistant ring. That is, in the example shown in FIG. 8A, the first portion that virtually defines the shape of the outer edge of the insulating layer 140 is not influenced by the above-described concave portion. FIG. 8B shows a modification of the arrangement example shown in FIG. 8A. In FIG. 8B, the outer edge of the insulating layer 140 has a shape obtained by expanding, in an outward direction, each corner in a shape formed by a plurality of sides parallel to a plurality of sides forming the outer shape of the moisture-resistant ring 120.

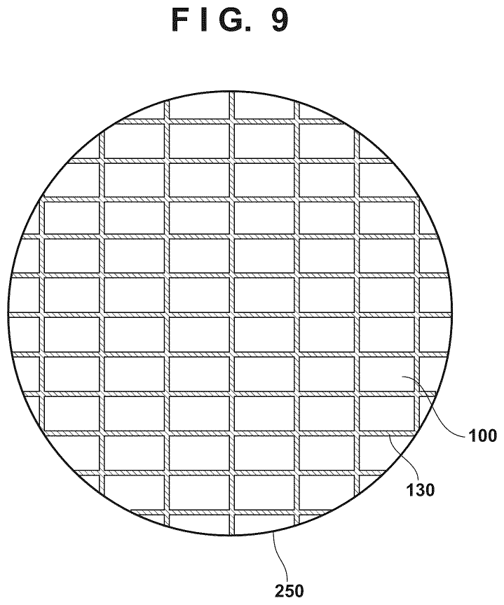

FIG. 9 is a plan view schematically showing the arrangement of an original substrate 250 with the plurality of light-emitting devices 100 arranged thereon in a manufacturing process. The original substrate 250 can also be called a wafer. The original substrate 250 is provided with a scribe area 130 dividing the plurality of light-emitting devices 100. The original substrate 250 is separated into the plurality of light-emitting devices 100 by dicing. Dicing is a step of cutting the original substrate 250 at the scribe area 130. As a dicing method, for example, blade dicing, in which a rotating grindstone is rotated at high speed to cut the original substrate, or stealth dicing, in which a modified layer is formed inside the original substrate by condensing laser light inside the original substrate and then an external force is applied to cut the original substrate, can be employed. If the insulating layer 140 exists in the scribe area 130, this serves as a film that inhibits dicing, so that the insulating layer 140 on the center line of the scribe area 130 is removed.

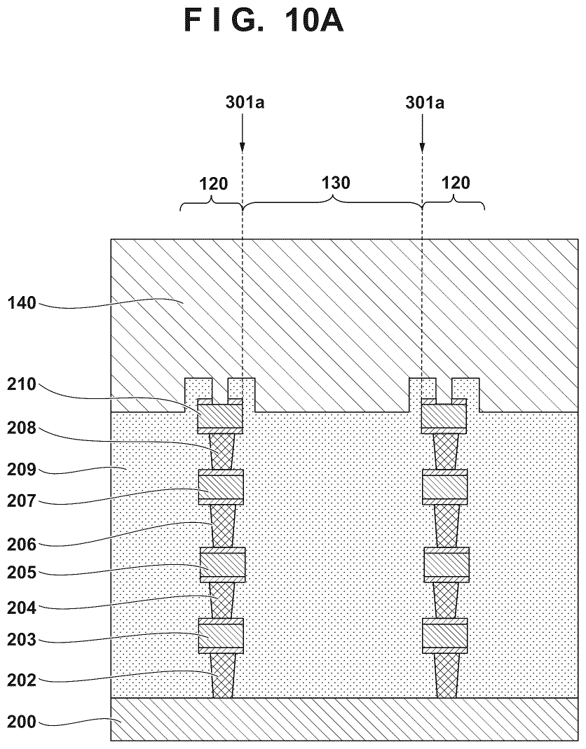

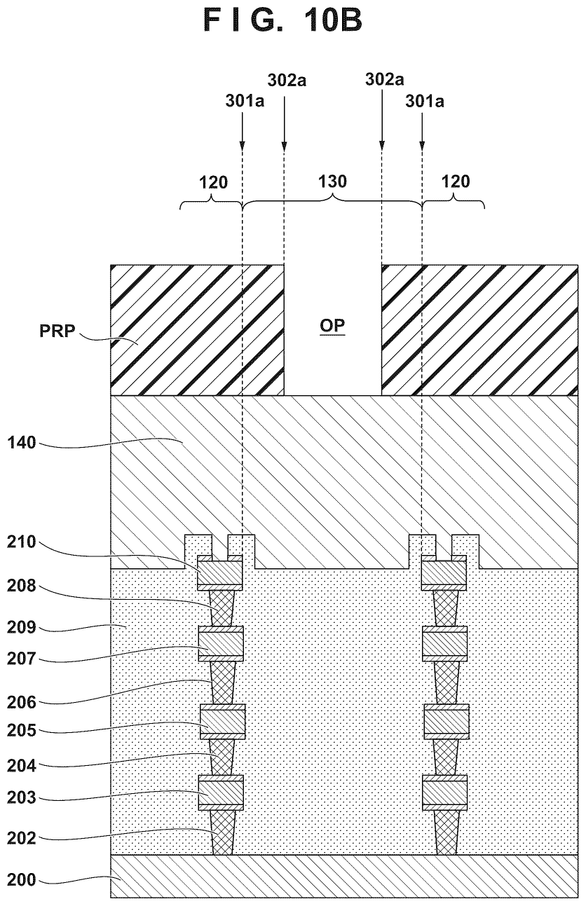

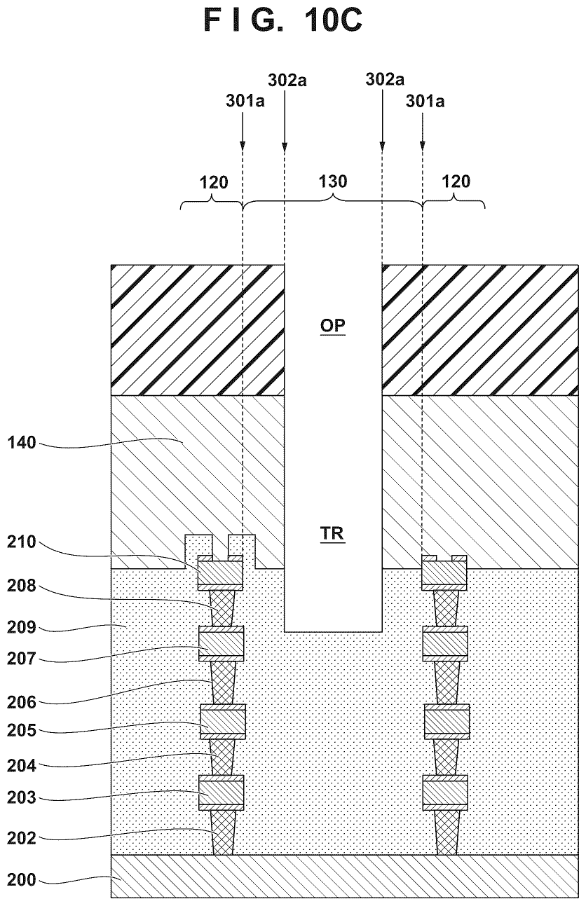

With reference to FIGS. 10A to 10C, the procedure of a process of forming a trench by etching the insulating layer 140 and an insulating layer 209 arranged in the scribe area 130 will be described below. Each of FIGS. 10A to 10C is a schematic sectional view showing the vicinity of the scribe area 130 during the process of forming the trench in the scribe area 130.

FIG. 10A schematically shows the sectional structure before an opening is formed in the scribe area 130. The outer edge of the scribe area 130 can be defined as end portions 301a of the moisture-resistant rings 120 of two adjacent light-emitting devices 100. The insulating layer 140 can be, for example, a single film of a silicon nitride film formed by a plasma CVD method, or a three-layer structure including two silicon nitride films formed by a plasma CVD method and an alumina film (Al₂O₃) arranged therebetween formed by an ALD method. The insulating layer 140 is preferably formed from a film having a lower moisture permeability than the insulating layer 209, and in this case, the insulating layer 140 can serve as a blocking film that blocks moisture entering from the outside.

First, as schematically shown in FIG. 10B, a photoresist pattern PRP is formed by a photolithography step. The photoresist pattern PRP includes an opening OP used to form a trench by etching the insulating layer 140 and the insulating layer 209. In order to prevent the insulating layer 140 arranged on the moisture-resistant ring 120 from being removed by etching, the opening OP of the photoresist pattern PRP is formed to have the outer edge at a position 302a away from the end portion 301a of the moisture-resistant ring 120.

Next, as schematically shown in FIG. 10C, through the opening OP of the photoresist pattern PRP, the insulating layer 140 and the insulating layer 209 are etched by anisotropic etching, thereby forming a trench TR in the scribe area 130. Thereafter, the photoresist pattern PRP is removed. For the anisotropic etching, for example, plasma etching (RIE) using a C₄F₈- or CF₄-based gas can be employed.

Next, an organic light-emitting element that is applicable as the light-emitting element in the above-described light-emitting device 100 will be described. The organic light-emitting element includes a first electrode, a second electrode, and an organic compound layer arranged between these electrodes. One of the first electrode and the second electrode is an anode, and the other is a cathode. In the organic light-emitting element according to this embodiment, the organic compound layer may be either a single layer or a stacked body formed by a plurality of layers as long as it includes a light-emitting layer. Here, if the organic compound layer is a stacked body formed from a plurality of layers, the organic compound layer may include a hole injection layer, a hole transport layer, an electron blocking layer, a hole/exciton blocking layer, an electron transport layer, an electron injection layer, and the like in addition to the light-emitting layer. The light-emitting layer may be a single layer or a stacked body formed from a plurality of layers. If the light-emitting layer includes a plurality of layers, a charge generation layer may be arranged between the light-emitting layers. The charge generation layer may be made of a compound having the lowest unoccupied molecular orbital (LUMO) lower than that of the hole transport layer, and the LUMO of the charge generation layer may be lower than the highest occupied molecular orbital (HOMO) of the hole transport layer. Here, the molecular orbital energy of the organic compound layer may be the molecular orbital energy of the organic compound with the largest weight ratio in the organic compound layer.

The description is given here assuming that the closer the HOMO and LUMO are to the vacuum level, the “higher” they are. When the LUMO of the charge generation layer is lower than the HOMO of the hole transport layer, the LUMO of the charge generation layer is closer to the vacuum level than the HOMO of the hole transport layer.

The HOMO and LUMO in this specification can be calculated using molecular orbital calculation. The molecular orbital calculation is executed by a Density Functional Theory (DFT) or the like. A functional may be calculated using B3LYP, and a basic function may be calculated using 6-31G*, or the like. Note that molecular orbital calculation can be executed using, for example, Gaussian 09 (Gaussian 09, Revision C.01, M. J. Frisch, G. W. Trucks, H. B. Schlegel, G. E. Scuseria, M. A. Robb, J. R. Cheeseman, G. Scalmani, V. Barone, B. Mennucci, G. A. Petersson, H. Nakatsuji, M. Caricato, X. Li, H. P. Hratchian, A. F. Izmaylov, J. Bloino, G. Zheng, J. L. Sonnenberg, M. Hada, M. Ehara, K. Toyota, R. Fukuda, J. Hasegawa, M. Ishida, T. Nakajima, Y. Honda, O. Kitao, H. Nakai, T. Vreven, J. A. Montgomery Jr., J. E. Peralta, F. Ogliaro, M. Bearpark, J. J. Heyd, E. Brothers, K. N. Kudin, V. N. Staroverov, T. Keith, R. Kobayashi, J. Normand, K. Raghavachari, A. Rendell, J. C. Burant, S. S. Iyengar, J. Tomasi, M. Cossi, N. Rega, J. M. Millam, M. Klene, J. E. Knox, J. B. Cross, V. Bakken, C. Adamo, J. Jaramillo, R. Gomperts, R. E. Stratmann, O. Yazyev, A. J. Austin, R. Cammi, C. Pomelli, J. W. Ochterski, R. L. Martin, K. Morokuma, V. G. Zakrzewski, G. A. Voth, P. Salvador, J. J. Dannenberg, S. Dapprich, A. D. Daniels, O. Farkas, J. B. Foresman, J. V. Ortiz, J. Cioslowski, and D. J. Fox, Gaussian, Inc., Wallingford CT, 2010.)

The HOMO and LUMO in this specification can be calculated using the ionization potential and band gap. The HOMO can be estimated by measuring the ionization potential. The ionization potential can be measured by dissolving the compound to be measured in a solvent such as toluene and using a measuring device such as AC-3. The band gap can be measured by measurement in which the compound to be measured is dissolved in a solvent such as toluene, and it is irradiated with excitation light. The band gap can be measured by measuring the absorption edge of the excitation light. Alternatively, the band gap can be measured by depositing the compound to be measured on a substrate such as glass, and exposing the deposited film to excitation light. The band gap can be measured by measuring the absorption edge of the absorption spectrum at which the deposited film absorbs excitation light.

The LUMO can be calculated using the band gap and ionization potential value. The LUMO can be estimated by subtracting the ionization potential value from the band gap.

The LUMO can also be estimated from the reduction potential. For example, the one-electron reduction potential is estimated using cyclic voltammetry (CV) measurement. The CV measurement can be performed, for example, in a dimethylformamide (DMF) solution of 0.1 M tetrabutylammonium perchlorate using a reference electrode of Ag/Ag⁺, a counter electrode of Pt, and a working electrode of glassy carbon. The LUMO can be estimated by adding −4.8 electron volt (eV) to the difference between the reduction potential of the obtained compound and that of ferrocene.

A conventionally known low molecular and high molecular hole injection compound or hole transport compound, a compound serving as a host, a light-emitting compound, an electron injection compound or electron transport compound, or the like can be used together as desired. Examples of these compounds will be described below.

As a hole injection/transport material, a material that has a high hole mobility such that hole injection from the anode is facilitated, and injected holes can be transported to the light-emitting layer is preferably used. Also, a material having a high glass transition point temperature is preferably used to reduce degradation of film quality such as crystallization in the organic light-emitting element. Examples of low molecular and high molecular materials having hole injection/transport performance are a triarylamine derivative, an arylcarbazole derivative, a phenylenediamine derivative, a stilbene derivative, a phthalocyanine derivative, a porphyrin derivative, a poly(vinyl carbazole), a poly(thiophene), and other conductive polymers. The above-described hole injection/transport material can suitably be used for the electron blocking layer as well. Detailed examples of compounds used as the hole injection/transport material will be shown below. The material is not limited to these.

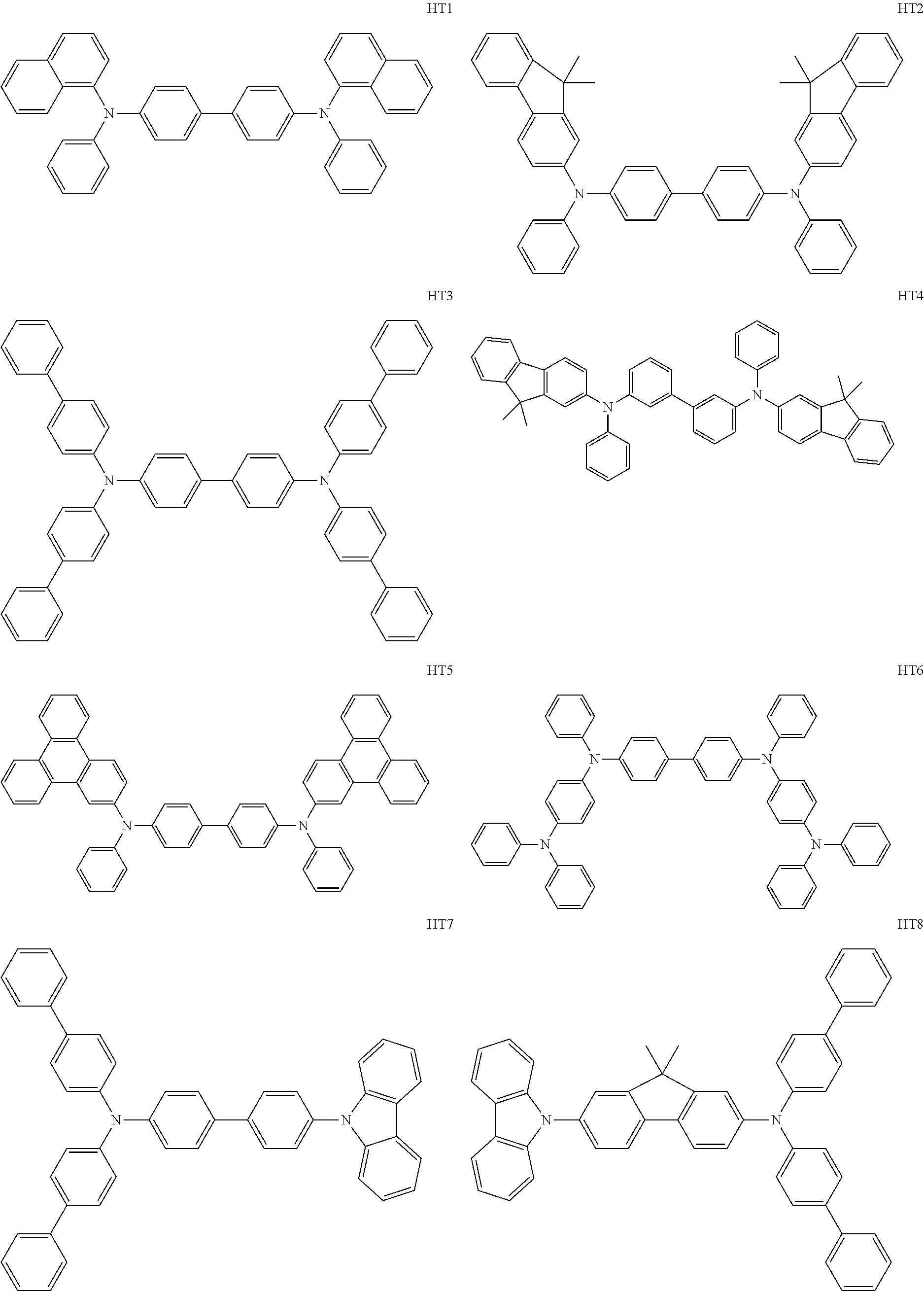

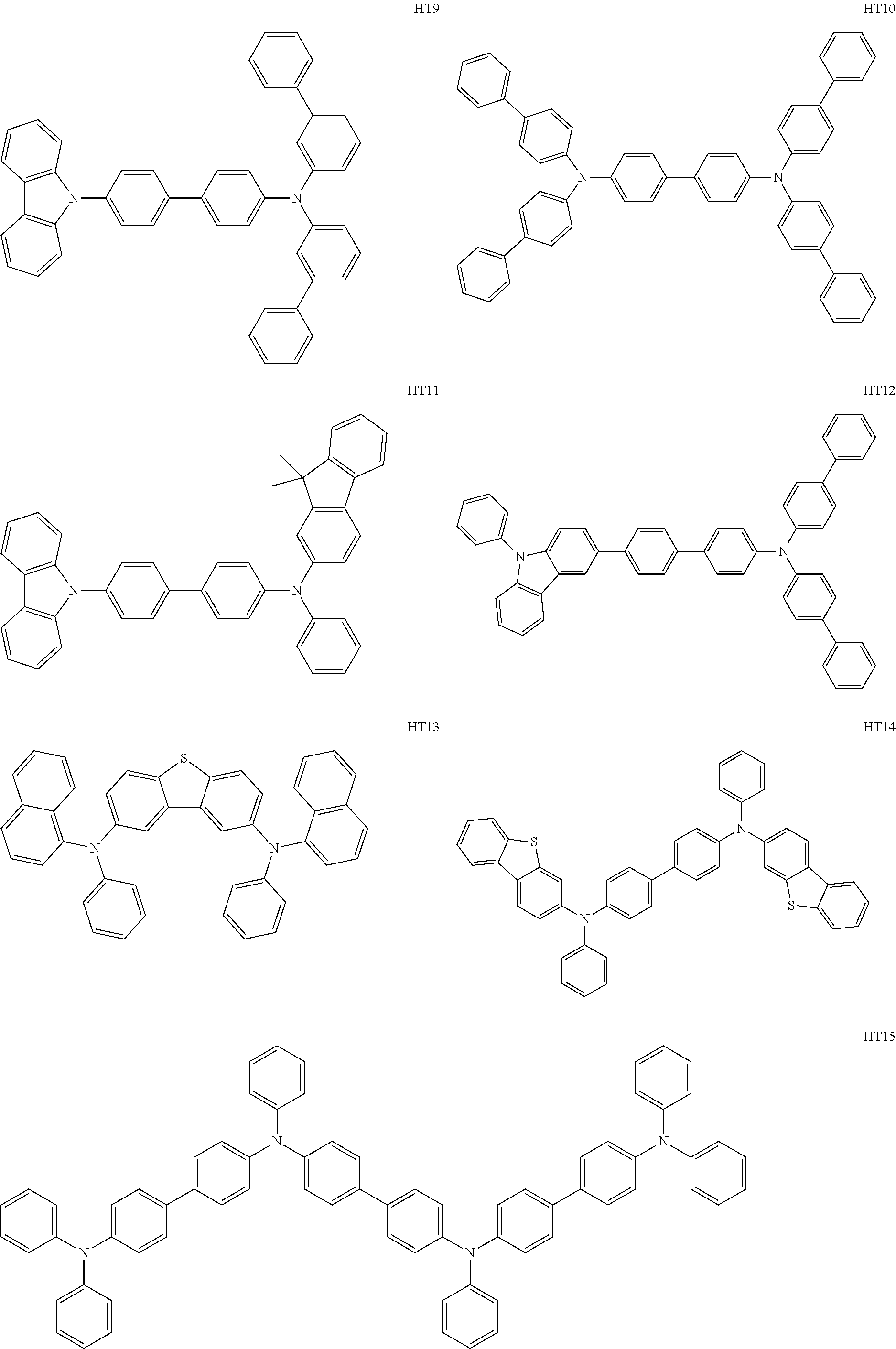

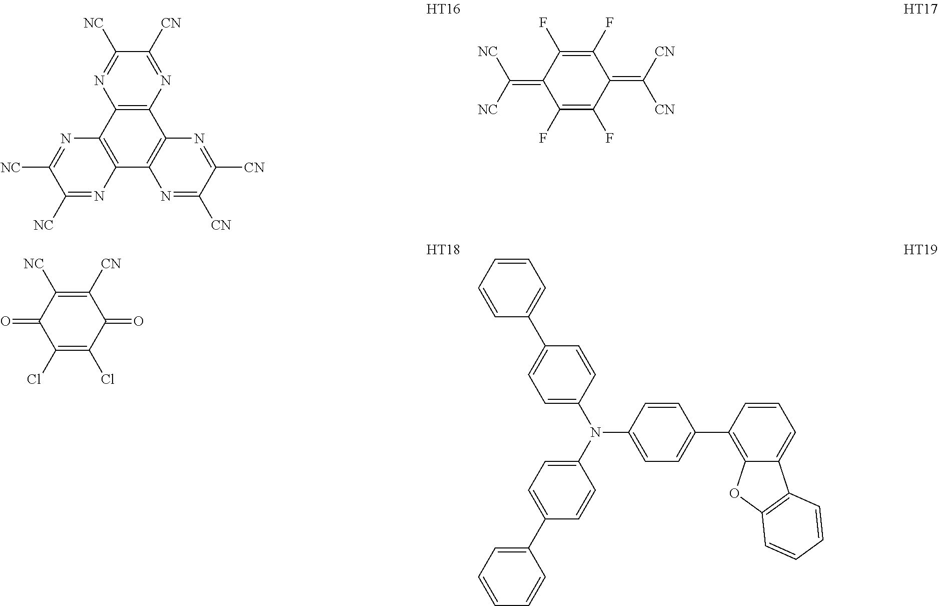

In the hole transport materials, HT16 to HT18 can decrease the driving voltage when used in a layer in contact with the anode. HT16 is widely used in an organic light-emitting element. HT2, HT3, HT4, HT5, HT6, HT10, and HT12 can be used in an organic compound layer adjacent to HT16. A plurality of materials may be used in one organic compound layer.

Examples of the light-emitting material mainly concerning the light-emitting function are condensed-ring compounds (for example, a fluorene derivative, a naphthalene derivative, a pyrene derivative, a perylene derivative, a tetracene derivative, an anthracene derivative, and rubrene), a quinacridone derivative, a coumarin derivative, a stilbene derivative, an organic aluminum complex such as tris(8-quinolinolato) aluminum, an iridium complex, a platinum complex, a rhenium complex, a copper complex, a europium complex, a ruthenium complex, and polymer derivatives such as a poly(phenylenevinylene) derivative, a poly(fluorene) derivative, and a poly(phenylene) derivative.

Detailed examples of compounds used as the light-emitting material will be shown below. The material is not limited to these.

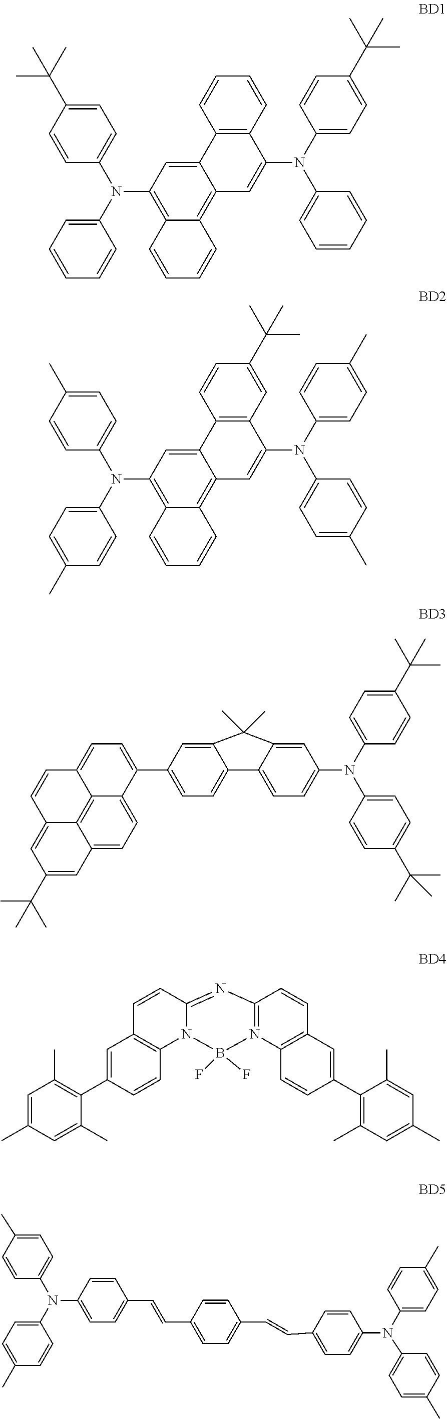

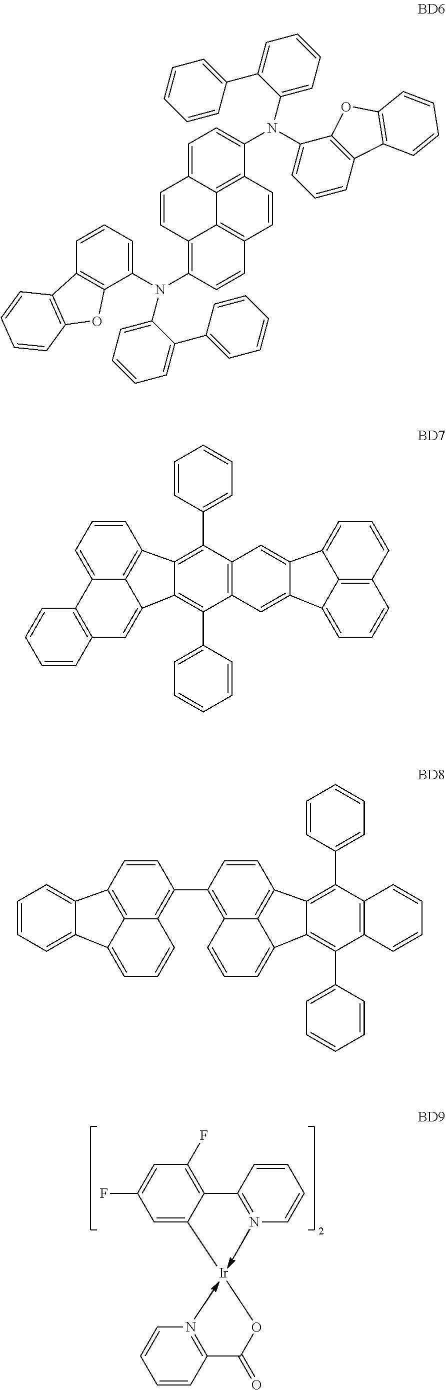

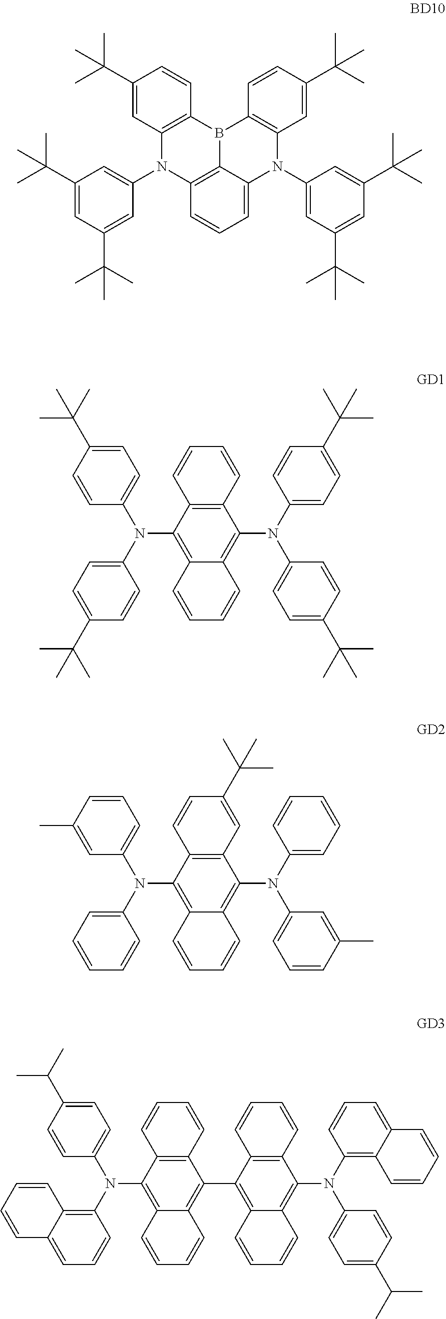

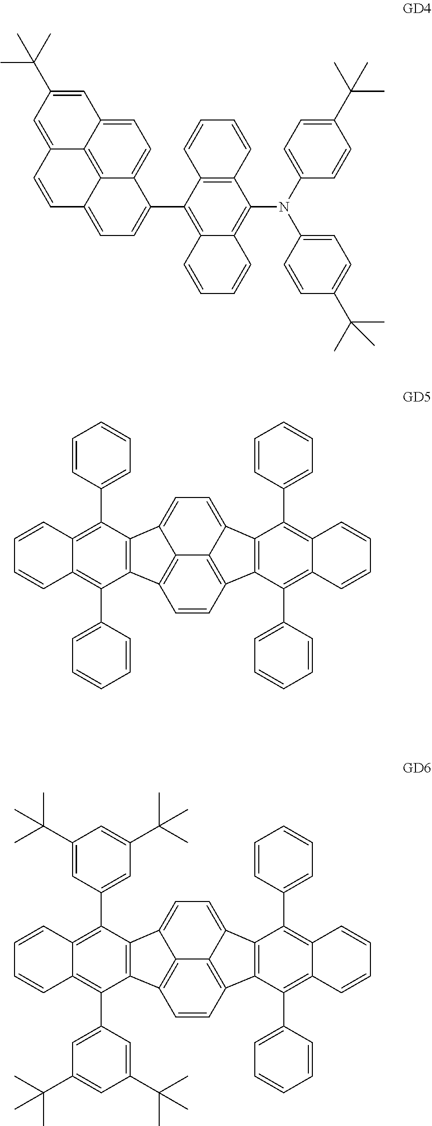

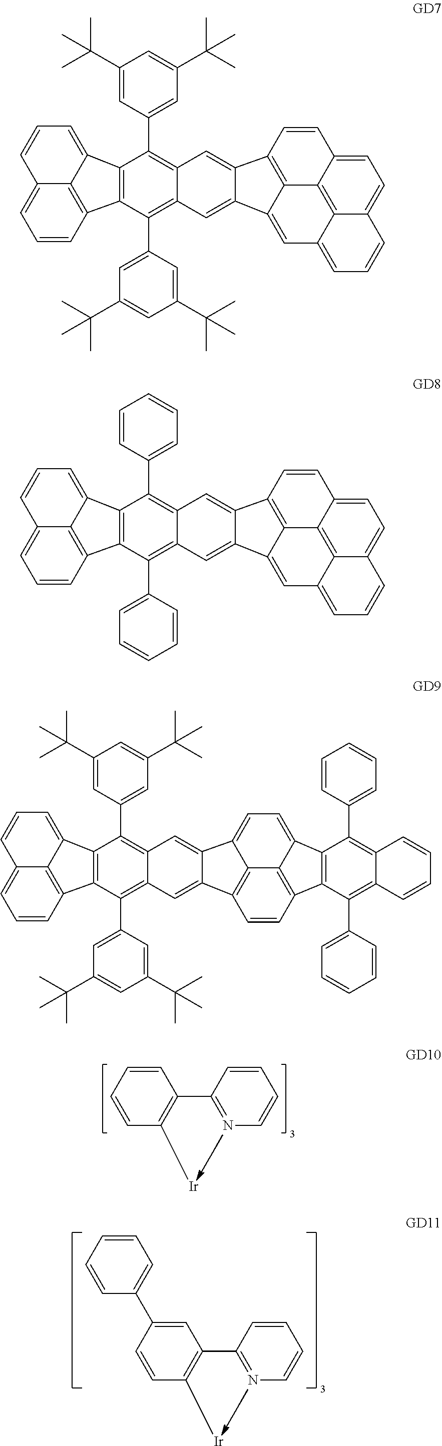

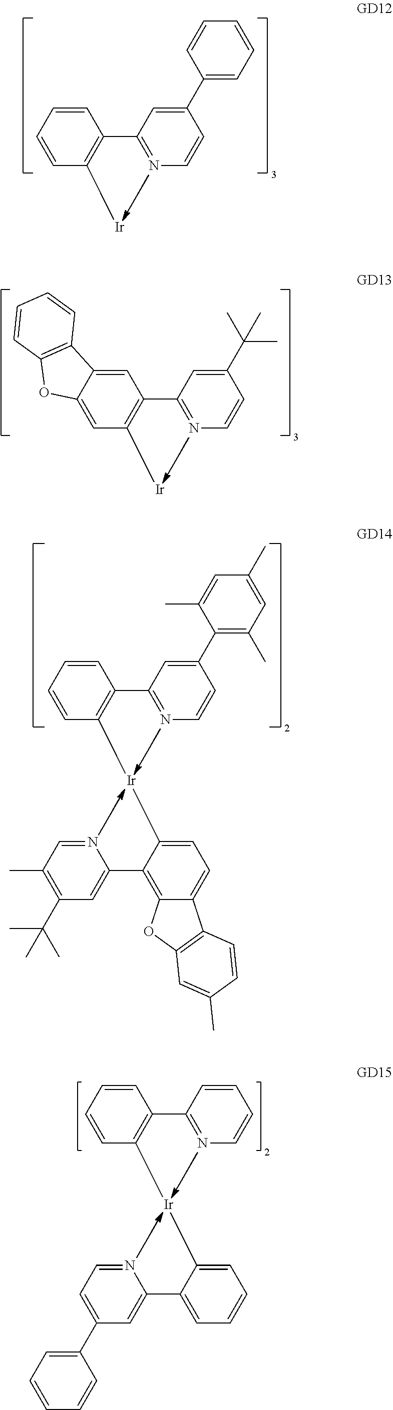

If the light-emitting material is a hydrocarbon compound, this is preferable because it is possible to reduce lowering of light emission efficiency caused by exciplex formation or lowering of color purity due to a change of the light emission spectrum of the light-emitting material caused by exciplex formation.

The hydrocarbon compound is a compound made of only carbon and hydrogen, and includes BD7, BD8, GD5 to GD9, and RD1 in the compounds exemplified above.

If the light-emitting material is a condensed polycyclic compound including a 5-membered ring, this is preferable because oxidation hardly occurs because of a high ionization potential, and a long-life element with high durability can be obtained. This includes BD7, BD8, GD5 to GD9, and RD1 in the compounds exemplified above.

Examples of the light-emitting layer host or the light emission assist material contained in the light-emitting layer are an aromatic hydrocarbon compound or its derivative, a carbazole derivative, a dibenzofuran derivative, a dibenzothiophene derivative, an organic aluminum complex such as tris(8-quinolinolato) aluminum, and an organic beryllium complex.

Detailed examples of compounds used as the light-emitting layer host or the light emission assist material contained in the light-emitting layer will be shown below. The material is not limited to these.

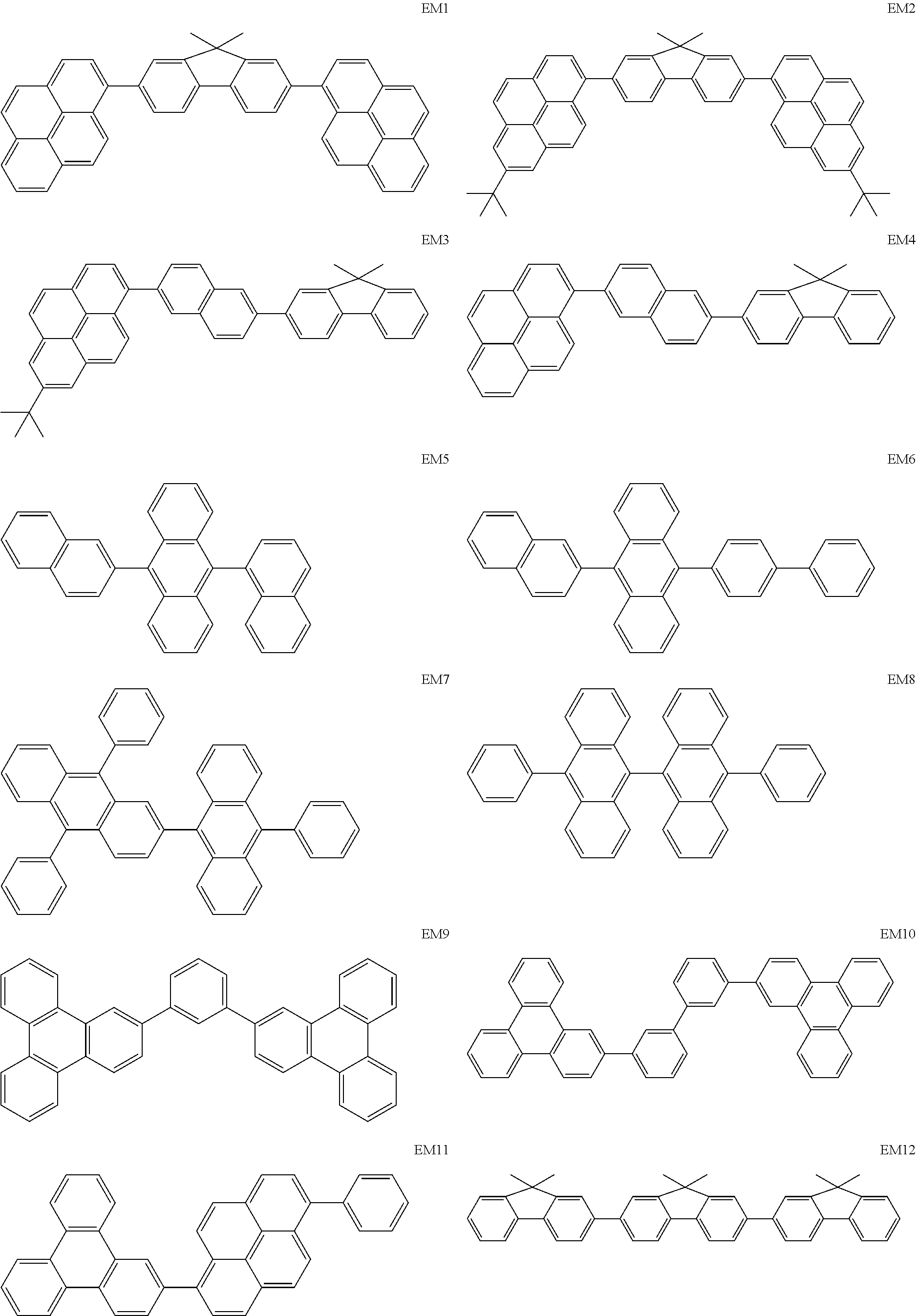

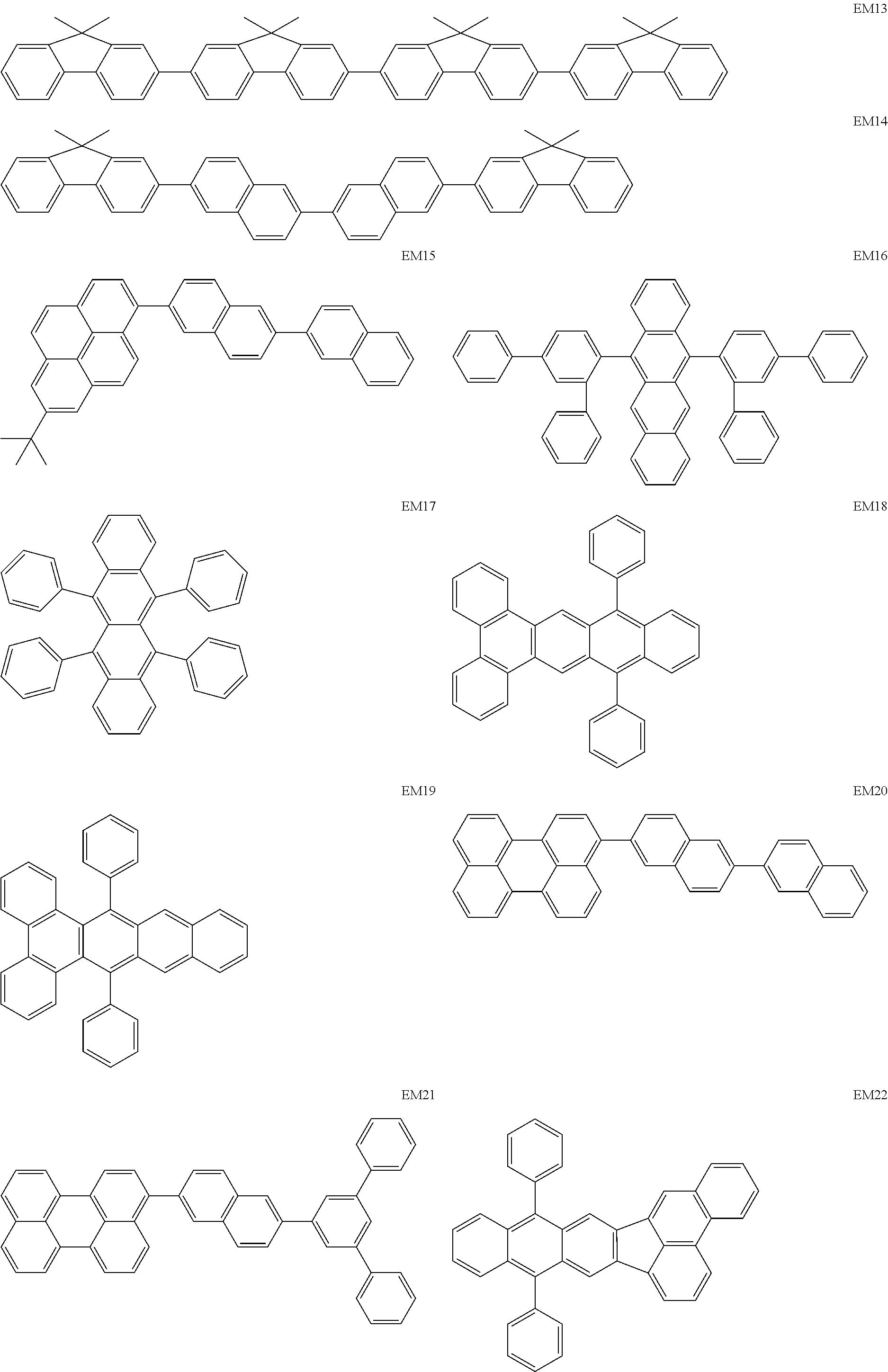

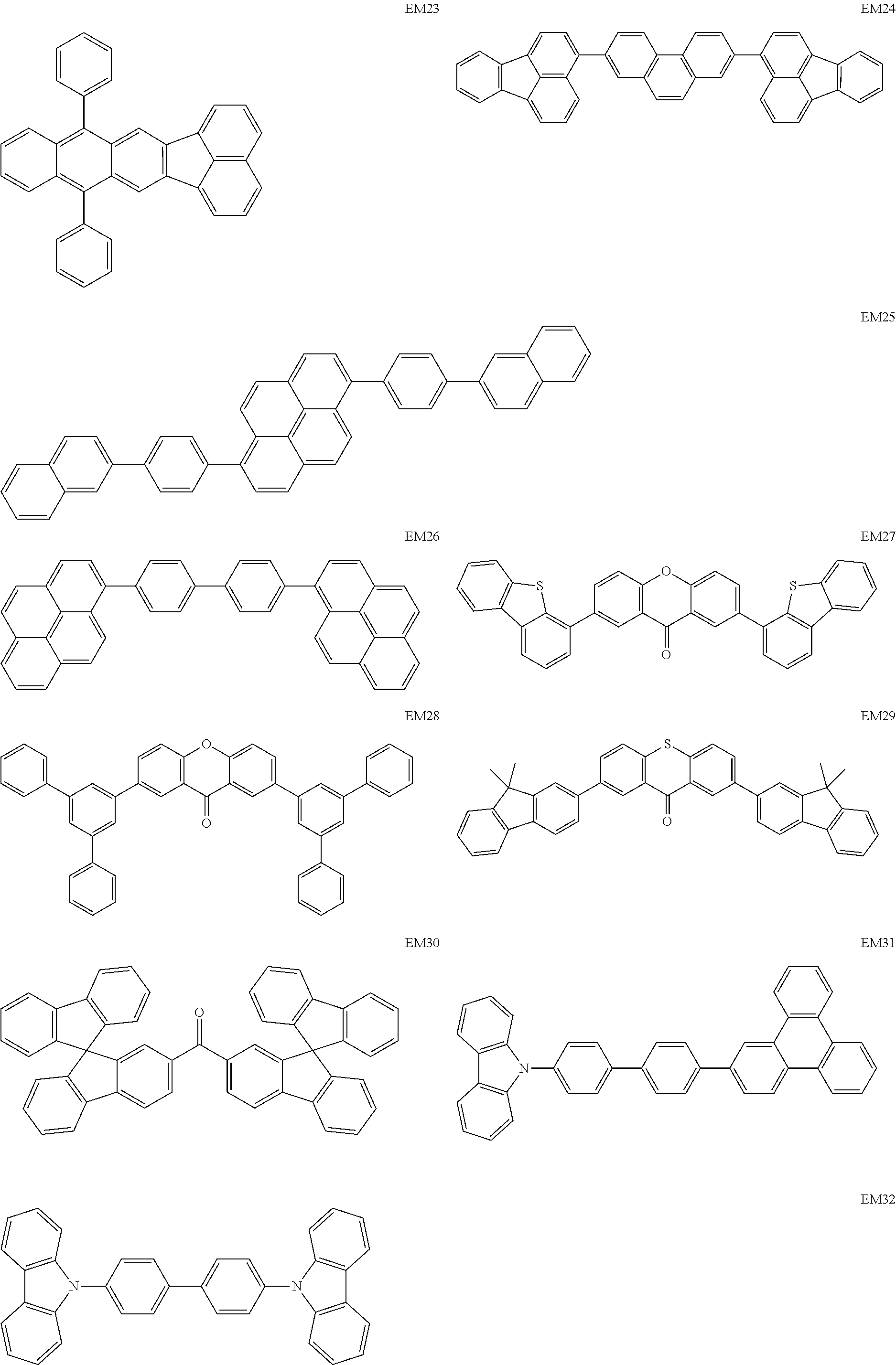

The host material may be a hydrocarbon compound. The hydrocarbon compound is a compound made of only carbon and hydrogen, and includes EM1 to EM12 and EM16 to EM27 in the compounds exemplified above. As the host material, a material that has, in a single bond that bonds an aryl group unit in its structure, no carbon-heteroatom bonds, like F3 in compound 1, is suitable from the viewpoint of stability.

The electron transport material can arbitrarily be selected from materials capable of transporting electrons injected from the cathode to the light-emitting layer, and is selected in consideration of balance to the hole mobility of the hole transport material. Examples of the material having electron transport performance are an oxadiazole derivative, an oxazole derivative, a pyrazine derivative, a triazole derivative, a triazine derivative, a quinoline derivative, a quinoxaline derivative, a phenanthroline derivative, an organic aluminum complex, and condensed-ring compounds (for example, a fluorene derivative, a naphthalene derivative, a chrysene derivative, and an anthracene derivative). The above-described electron transport material is suitably used for the hole blocking layer as well.

Detailed examples of compounds used as the electron transport material will be shown below. The material is not limited to these.

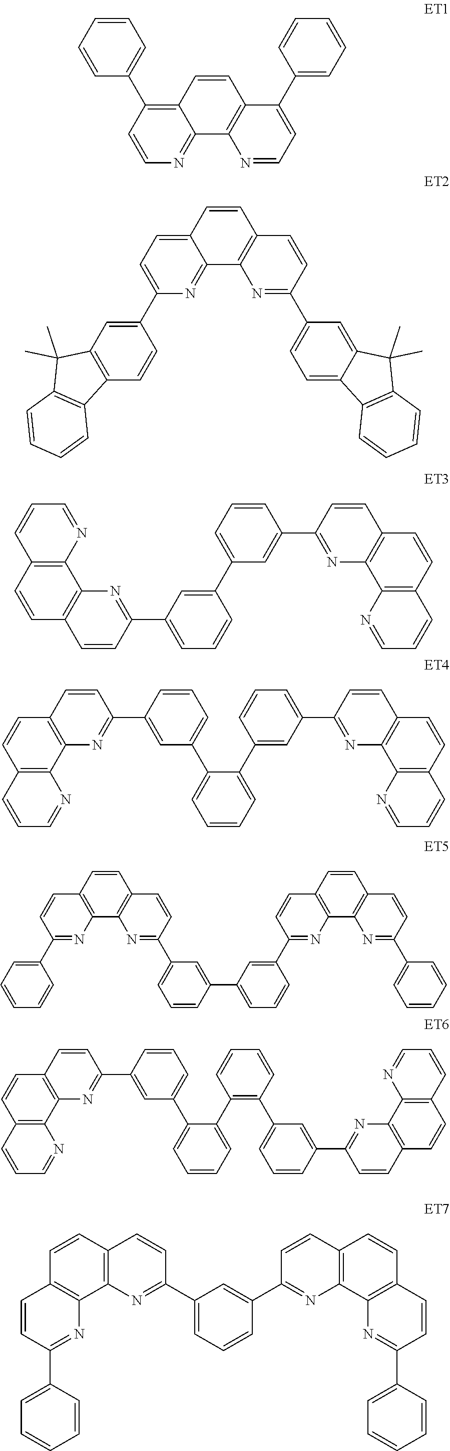

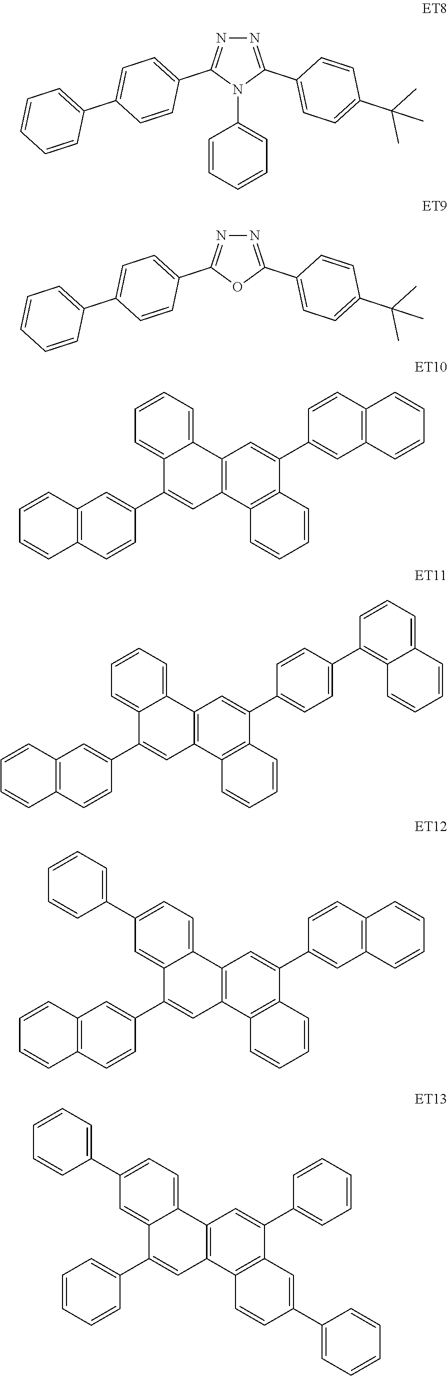

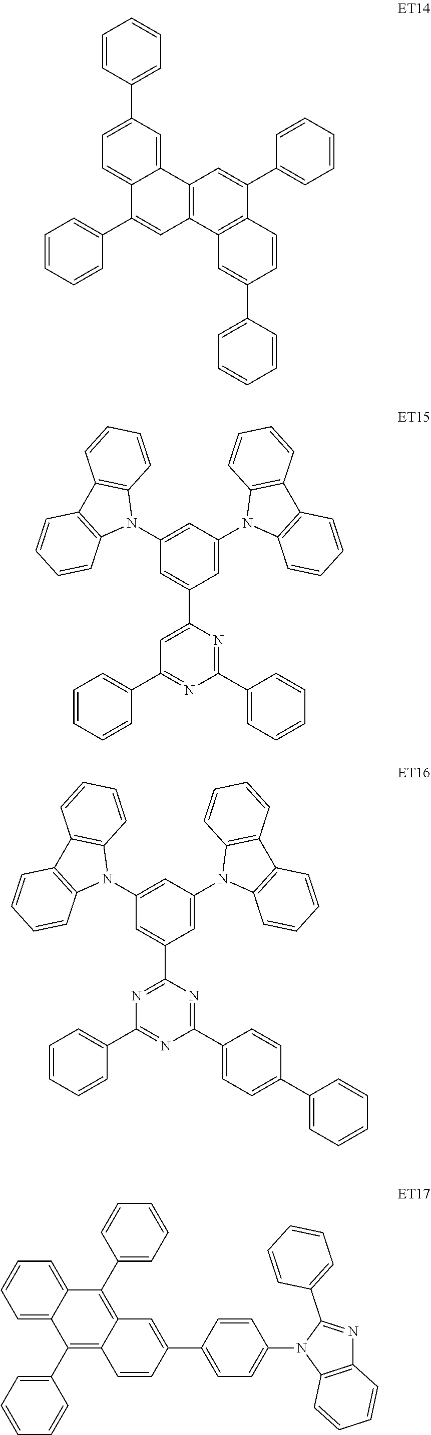

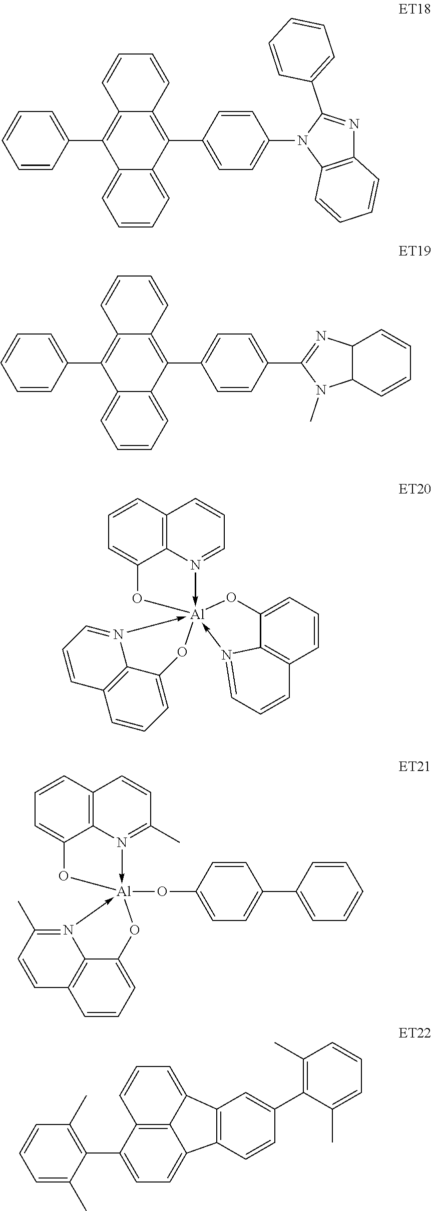

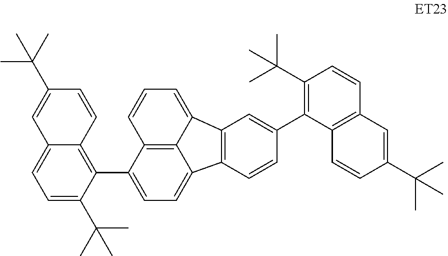 [SMILES: CC(C)(C)c1ccc2c(-c3ccc4c(c3)-c3cccc5c(-c6c(C(C)(C)C)ccc7cc(C(C)(C)C)ccc67)ccc-4c35)c(C(C)(C)C)ccc2c1]

The electron injection material can arbitrarily be selected from materials capable of facilitating electron injection from the cathode, and is selected in consideration of balance to hole injection. The organic compound includes an n-type dopant and a reducible dopant. Examples are a compound containing an alkali metal such as lithium fluoride, a lithium complex such as a lithium-quinolinol complex, a benzo-imidazolidene derivative, an imidazolidene derivative, a fulvalene derivative, and an acridine derivative.

The electron injection material can also be used together with the above-described electron transport material.

### Configuration of Organic Light-Emitting Element

The organic light-emitting element is provided by forming an insulating layer, a first electrode, an organic compound layer, and a second electrode on a substrate. A protection layer, a color filter, a microlens, and the like may be provided on a cathode. If a color filter is provided, a planarizing layer can be provided between the protection layer and the color filter. The planarizing layer can be made of acrylic resin or the like. The same applies to a case in which a planarizing layer is provided between the color filter and the microlens.

### Substrate

Quartz, glass, a silicon wafer, a resin, a metal, or the like may be used as a substrate. Furthermore, a switching element such as a transistor and a wiring may be provided on the substrate, and an insulating layer may be provided thereon. The insulating layer may be made of any material as long as a contact hole can be formed so that the wiring can be formed between the insulating layer and the first electrode and insulation from the unconnected wiring can be ensured. For example, a resin such as polyimide, silicon oxide, silicon nitride, or the like can be used.

### Electrode

A pair of electrodes can be used as the electrodes. The pair of electrodes can be an anode and a cathode. If an electric field is applied in the direction in which the organic light-emitting element emits light, the electrode having a high potential is the anode, and the other is the cathode. It can also be said that the electrode that supplies holes to the light-emitting layer is the anode and the electrode that supplies electrons is the cathode.

As the constituent material of the anode, a material having a work function as large as possible is preferably used. For example, a metal such as gold, platinum, silver, copper, nickel, palladium, cobalt, selenium, vanadium, or tungsten, a mixture containing some of them, an alloy obtained by combining some of them, or a metal oxide such as tin oxide, zinc oxide, indium oxide, indium tin oxide (ITO), or zinc indium oxide can be used. Furthermore, a conductive polymer such as polyaniline, polypyrrole, or polythiophene can also be used.

One of these electrode materials may be used singly, or two or more of them may be used in combination. The anode may be formed by a single layer or a plurality of layers.

If the anode is used as a reflective electrode, for example, chromium, aluminum, silver, titanium, tungsten, molybdenum, an alloy thereof, a stacked layer thereof, or the like can be used. The above materials can function as a reflective film having no role as an electrode. If the anode is used as a transparent electrode, an oxide transparent conductive layer made of indium tin oxide (ITO), indium zinc oxide, or the like can be used, but the present disclosure is not limited thereto. A photolithography technique can be used to form the electrode.

On the other hand, as the constituent material of the cathode, a material having a small work function is preferably used. Examples of the material include an alkali metal such as lithium, an alkaline earth metal such as calcium, a metal such as aluminum, titanium, manganese, silver, lead, or chromium, and a mixture containing some of them. Alternatively, an alloy obtained by combining these metals can also be used. For example, a magnesium-silver alloy, an aluminum-lithium alloy, an aluminum-magnesium alloy, a silver-copper alloy, a zinc-silver alloy, or the like can be used. A metal oxide such as indium tin oxide (ITO) can also be used. One of these electrode materials may be used singly, or two or more of them may be used in combination. The cathode may have a single-layer structure or a multilayer structure. Among others, silver is preferably used. To suppress aggregation of silver, a silver alloy is more preferably used. The ratio of the alloy is not limited as long as aggregation of silver can be suppressed. For example, the ratio between silver and another metal may be 1:1, 3:1, or the like.

The cathode may be a top emission element using an oxide conductive layer made of ITO or the like, or may be a bottom emission element using a reflective electrode made of aluminum (Al) or the like, and is not particularly limited. The method of forming the cathode is not particularly limited, but direct current sputtering or alternating current sputtering is preferably used since the good film coverage is provided and the resistance is easily lowered.

### Pixel Isolation Layer

A pixel isolation layer is formed by a silicon nitride (SiN) film, a silicon oxynitride (SiON) film, or a silicon oxide (SiO) film formed using a Chemical Vapor Deposition method (CVD method). To increase the resistance in the in-plane direction of the organic compound layer, the organic compound layer, especially the hole transport layer is preferably thinly deposited on the side wall of the pixel isolation layer. More specifically, the organic compound layer can be deposited so as to have a thin film thickness on the side wall by increasing the taper angle of the side wall of the pixel isolation layer or the film thickness of the pixel isolation layer to increase vignetting during vapor deposition.

On the other hand, it is preferable to adjust the taper angle of the side wall of the pixel isolation layer or the film thickness of the pixel isolation layer to the extent that no space is formed in the protection layer formed on the pixel isolation layer. Since no space is formed in the protection layer, it is possible to reduce generation of defects in the protection layer. Since generation of defects in the protection layer is reduced, a decrease in reliability caused by generation of a dark spot or occurrence of a conductive failure of the second electrode can be reduced.

According to this embodiment, even if the taper angle of the side wall of the pixel isolation layer is not acute, it is possible to effectively suppress leakage of charges to an adjacent pixel. As a result of this consideration, it has been found that the taper angle of 60° (inclusive) to 90° (inclusive) can sufficiently reduce the occurrence of defects. The film thickness of the pixel isolation layer is desirably 10 nanometer (nm) (inclusive) to 150 nm (inclusive). A similar effect can be obtained in a configuration including only pixel electrodes without the pixel isolation layer. However, in this case, the film thickness of the pixel electrode is preferably set to be equal to or smaller than half the film thickness of the organic layer or the end portion of the pixel electrode is preferably formed to have a forward tapered shape of less than 60° because short circuit of the organic light-emitting element can be reduced.

### Organic Compound Layer

The organic compound layer may be formed by a single layer or a plurality of layers. If the organic compound layer includes a plurality of layers, the layers can be called a hole injection layer, a hole transport layer, an electron blocking layer, a light-emitting layer, a hole blocking layer, an electron transport layer, and an electron injection layer in accordance with the functions of the layers. The organic compound layer is mainly formed from an organic compound but may contain inorganic atoms and an inorganic compound. For example, the organic compound layer may contain copper, lithium, magnesium, aluminum, iridium, platinum, molybdenum, zinc, or the like. The organic compound layer can be arranged between the first and second electrodes, and may be arranged in contact with the first and second electrodes.

If a plurality of light-emitting layers is provided, a charge generation portion may be arranged between the first light-emitting layer and the second light-emitting layer. The charge generation portion may contain an organic compound with a lowest unoccupied molecular orbital energy (LUMO) of −5.0 eV or less. The same applies to a case where a charge generation portion is provided between the second light-emitting layer and the third light-emitting layer.

### Protection Layer

A protection layer may be provided on the second electrode. For example, by adhering glass provided with a moisture absorbing agent on the second electrode, permeation of water or the like into the organic compound layer can be suppressed and occurrence of display defects can be suppressed. Furthermore, as another embodiment, a passivation film made of silicon nitride or the like may be provided on the cathode to suppress permeation of water or the like into the organic compound layer. For example, the protection layer can be formed by forming the cathode, transferring it to another chamber without breaking the vacuum, and forming a silicon nitride film having a thickness of 2 μm by a CVD method. The protection layer may be provided using an atomic deposition method (ALD method) after deposition using the CVD method. The material of the film by the ALD method is not limited but can be silicon nitride, silicon oxide, aluminum oxide, or the like. A silicon nitride film may further be formed by the CVD method on the film formed by the ALD method. The film formed by the ALD method may have a film thickness smaller than that of the film formed by the CVD method. More specifically, the film thickness of the film formed by the ALD method may be 50% or less, or 10% or less.

### Color Filter

A color filter may be provided on the protection layer. For example, a color filter considering the size of the organic light-emitting element may be provided on another substrate, and this substrate may be bonded to the substrate with the organic light-emitting element provided thereon. Alternatively, a color filter may be patterned on the above-described protection layer using a photolithography technique. The color filter can be formed from a polymeric material.

### Planarizing Layer

A planarizing layer may be provided between the color filter and the protection layer. The planarizing layer is provided to reduce unevenness of the lower layer. The planarizing layer may be called a material resin layer without limiting the purpose of the layer. The planarizing layer can be formed from an organic compound, and can be made of a low-molecular material or a polymeric material. However, a polymetric material is more preferable.

The planarizing layers may be provided above and below the color filter, and the same or different materials may be used for them. More specifically, examples of the material include polyvinyl carbazole resin, polycarbonate resin, polyester resin, ABS resin, acrylic resin, polyimide resin, phenol resin, epoxy resin, silicone resin, and urea resin.

### Microlens

The organic light-emitting device can include an optical member such as a microlens on the light emission side. The microlens can be made of acrylic resin, epoxy resin, or the like. The microlens can aim to increase the amount of light extracted from the organic light-emitting device and control the direction of light to be extracted. The microlens can have a hemispherical shape. If the microlens has a hemispherical shape, among tangents contacting the hemisphere, there is a tangent parallel to the insulating layer, and the contact between the tangent and the hemisphere is the vertex of the microlens. The vertex of the microlens can be decided in the same manner even in an arbitrary sectional view. That is, among tangents contacting the semicircle of the microlens in a sectional view, there is a tangent parallel to the insulating layer, and the contact between the tangent and the semicircle is the vertex of the microlens.

Furthermore, the middle point of the microlens can also be defined. In the section of the microlens, a line segment from a point at which an arc shape ends to a point at which another arc shape ends is assumed, and the middle point of the line segment can be called the middle point of the microlens. A section for determining the vertex and the middle point may be a section perpendicular to the insulating layer.

The microlens includes a first surface including a convex portion and a second surface opposite to the first surface. The second surface is preferably arranged on the functional layer side of the first surface. For this configuration, the microlens may be formed on the light-emitting device. If the functional layer is an organic layer, it is preferable to avoid a process which produces high temperature in the manufacturing step. In addition, if it is configured to arrange the second surface on the functional layer side of the first surface, all the glass transition temperatures of an organic compound forming the organic layer are preferably 100° C. or more, and more preferably 130° C. or more.

### Counter Substrate

A counter substrate can be provided on the planarizing layer. The counter substrate is called a counter substrate because it is provided at a position corresponding to the above-described substrate. The constituent material of the counter substrate can be the same as that of the above-described substrate. If the above-described substrate is the first substrate, the counter substrate can be the second substrate.

### Organic Layer

The organic compound layer (hole injection layer, hole transport layer, electron blocking layer, light-emitting layer, hole blocking layer, electron transport layer, electron injection layer, and the like) forming the organic light-emitting element according to an embodiment of the present disclosure is formed by the method to be described below.

The organic compound layer forming the organic light-emitting element according to the embodiment of the present disclosure can be formed by a dry process using a vacuum deposition method, an ionization deposition method, a sputtering method, a plasma method, or the like. Instead of the dry process, a wet process that forms a layer by dissolving a solute in an appropriate solvent and using a well-known coating method (for example, a spin coating method, a dipping method, a casting method, an LB method, an inkjet method, or the like) can be used.

Here, when the layer is formed by a vacuum deposition method, a solution coating method, or the like, crystallization or the like hardly occurs and excellent temporal stability is obtained. Furthermore, when the layer is formed using a coating method, it is possible to form the film in combination with a suitable binder resin.

Examples of the binder resin include polyvinyl carbazole resin, polycarbonate resin, polyester resin, ABS resin, acrylic resin, polyimide resin, phenol resin, epoxy resin, silicone resin, and urea resin. However, the binder resin is not limited to them.

One of these binder resins may be used singly as a homopolymer or a copolymer, or two or more of them may be used in combination. Furthermore, additives such as a well-known plasticizer, antioxidant, and an ultraviolet absorber may also be used as desired.

### Pixel Circuit

The light-emitting device can include a pixel circuit connected to the light-emitting element. The pixel circuit may be an active matrix circuit that individually controls light emission of the first and second light-emitting elements. The active matrix circuit may be a voltage or current programing circuit. A driving circuit includes a pixel circuit for each pixel. The pixel circuit can include a light-emitting element, a transistor for controlling light emission luminance of the light-emitting element, a transistor for controlling a light emission timing, a capacitor for holding the gate voltage of the transistor for controlling the light emission luminance, and a transistor for connection to GND without intervention of the light-emitting element.

The light-emitting device includes a display region and a peripheral region arranged around the display region. The light-emitting device includes the pixel circuit in the display region and a display control circuit in the peripheral region. The mobility of the transistor forming the pixel circuit may be smaller than that of a transistor forming the display control circuit.

The slope of the current-voltage characteristic of the transistor forming the pixel circuit may be smaller than that of the current-voltage characteristic of the transistor forming the display control circuit. The slope of the current-voltage characteristic can be measured by a so-called Vg-Ig characteristic.

The transistor forming the pixel circuit is a transistor connected to the light-emitting element such as the first light-emitting element.

### Pixel

The organic light-emitting device includes a plurality of pixels. Each pixel includes sub-pixels that emit light components of different colors. The sub-pixels include, for example, R, G, and B emission colors, respectively.

In each pixel, a region also called a pixel opening emits light. This region is the same as the first region. The pixel opening can have a size of 5 μm (inclusive) to 15 μm (inclusive). More specifically, the pixel opening can have a size of 11 μm, 9.5 μm, 7.4 μm, 6.4 μm, or the like.

A distance between the sub-pixels can be 10 μm or less, and can be, more specifically, 8 μm, 7.4 μm, or 6.4 μm.

The pixels can have a known arrangement form in a plan view. For example, the pixels may have a stripe arrangement, a delta arrangement, a pentile arrangement, or a Bayer arrangement. The shape of each sub-pixel in a plan view may be any known shape. For example, a quadrangle such as a rectangle or a rhombus, a hexagon, or the like may be possible. Here, these shapes may not be correct shapes, and a shape close to a rectangle is included in a rectangle. The shape of the sub-pixel and the pixel arrangement can be used in combination.

### Application of Organic Light-Emitting Element of Embodiment of Present Disclosure

The organic light-emitting element according to an embodiment of the present disclosure can be used as a constituent member of a display apparatus or an illumination apparatus. In addition, the organic light-emitting element is applicable to the exposure light source of an electrophotographic image forming apparatus, the backlight of a liquid crystal display apparatus, a light-emitting device including a color filter in a white light source, and the like.

The display apparatus may be an image information processing apparatus that includes an image input unit for inputting image information from an area CCD, a linear CCD, a memory card, or the like, and an information processing unit for processing the input information, and displays the input image on a display unit.

In addition, a display unit included in an image capturing apparatus or an inkjet printer can have a touch panel function. The driving type of the touch panel function may be an infrared type, a capacitance type, a resistive film type, or an electromagnetic induction type, and is not particularly limited. The display apparatus may be used for the display unit of a multifunction printer.

Various apparatuses to which the above-described light-emitting device 100 is applied will be exemplarily described below. The apparatus may include a light-emitting device and a circuit for driving the light-emitting device, and can be implemented in various forms. The apparatus is, for example, an image forming apparatus, a camera, an information processing apparatus, or a moving body.

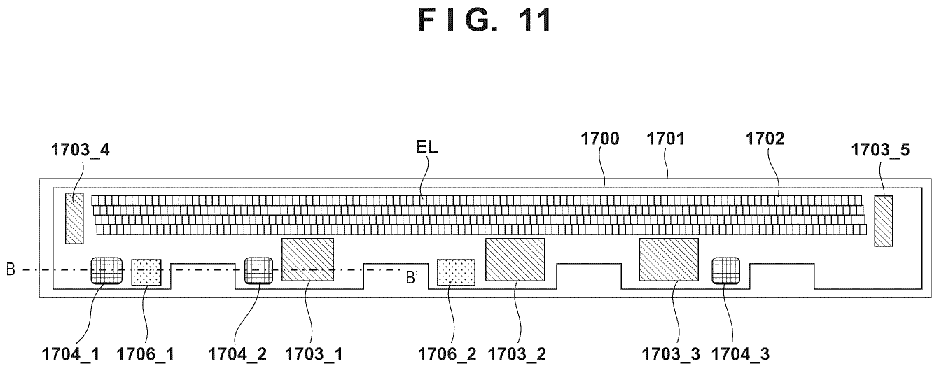

FIG. 11 is a schematic view showing the first application example of the light-emitting device 100. The light-emitting device of the first application example can be used as, for example, a light source of an image forming apparatus. The light-emitting device of the first application example can have a rectangular shape having long sides parallel to the first direction and short sides parallel to a direction intersecting the first direction. For example, the first direction may be a direction along the rotational axis direction of a photosensitive member of the image forming apparatus.

A substrate 1701 has a polygonal shape. An example of the substrate 1701 having a rectangular shape will be described here. In this specification, the long side direction of the rectangular substrate 1701 is called the first direction, and the short side direction orthogonal to the long side direction is called the second direction. The polygonal shape in the specification includes a shape having round corners. A moisture-resistant ring 1700 is placed on the rectangular substrate 1701. The moisture-resistant ring 1700 serves to suppress and prevent moisture from entering the light-emitting device. The moisture-resistant ring 1700 can be, for example, a guard ring formed from a wiring layer.

The moisture-resistant ring 1700 is internally provided with a light-emitting area 1702, contact regions 1703, pads 1704, and circuits 1706. The contact regions 1703 include, for example, a first contact region 1703_1, a second contact region 1703_2, and a third contact region 1703_3. The pads 1704 include, for example, a first pad 1704_1, a second pad 1704_2, and a third pad 1704_3.

The circuits 1706_1 and 1706_2 are circuits for driving light-emitting elements EL. Specific examples of the circuits include an input protection circuit, an input circuit to which each drive data is input, and a logic circuit for processing data. However, limitation is not made thereto.

The light-emitting elements EL are arrayed in the row and column directions in the light-emitting area 1702. The contact regions 1703 are regions where wirings electrically connected to the common electrodes of the light-emitting elements EL are arranged. The pad 1704_1 electrically connects the contact region 1703 to an external element.

The outer peripheral shape of the moisture-resistant ring 1700 may include a plurality of concave portions. These portions can be used as, for example, abutment regions on which ribs as parts of a mask for vapor deposition in a film forming process are made to abut.

Each of the plurality of light-emitting elements EL arrayed in a matrix pattern in the light-emitting area 1702 is constituted by a light-emitting layer and first and second electrodes sandwiching the light-emitting layer. An example is shown, in which the first electrode is an independent electrode individually provided for each light-emitting element EL, and the second electrode is a common electrode commonly provided for the plurality of light-emitting elements EL.

If, for example, the light-emitting elements EL are arranged on four rows in the light-emitting area 1702, the position of the first light-emitting element EL on the first row and the position of the first light-emitting element EL on the second row may be shifted from each other by ¼ of the X-direction size of the light-emitting element EL in the X direction, as exemplified in FIG. 11. In the case of n rows (where n is an integer of 2 or more), the position of the first light-emitting element EL on the first row and the position of the first light-emitting element EL on the second row may be shifted from each other by 1/n of the X-direction size of the light-emitting element EL in the X direction. Such arrangement is advantageous in improving the resolution.

The contact regions 1703 are adjacent regions of the light-emitting area 1702 of the substrate 1701 and arranged inside the moisture-resistant ring 1700. At least one of the first contact region 1703, the pad 1704, and the circuit 1706 may be placed between the light-emitting area 1702 and one of the long side end portions of the substrate 1701 together with the concave portion of the moisture-resistant ring 1700 and located in series with respect to the long side direction.

Providing the contact regions 1703, the pads 1704, and the circuits 1706 at positions in the same short side direction in this manner can reduce the length of the light-emitting device in the short side direction and downsize the light-emitting device.

The light-emitting device of the first application example includes the plurality of contact regions 1703 between the common electrodes and the power supply wirings of the light-emitting elements EL along the long side end of the light-emitting device. If, for example, the common electrode is made of a transparent electrode material having a relatively high electric resistance, the voltage drop amount sometimes increases in the long axis direction. The voltages applied to the respective light-emitting elements EL differ depending on the distances from the contact regions to which potentials are supplied. This causes differences in actual light emission luminance among the light-emitting elements EL to which voltages for light emission of the same luminance are applied, thus sometimes causing shading or the like. However, having the plurality of contact regions 1703 in the long axis direction can suppress voltage drops at the common electrodes in the long side direction, thereby suppressing the occurrence of shading or the like.

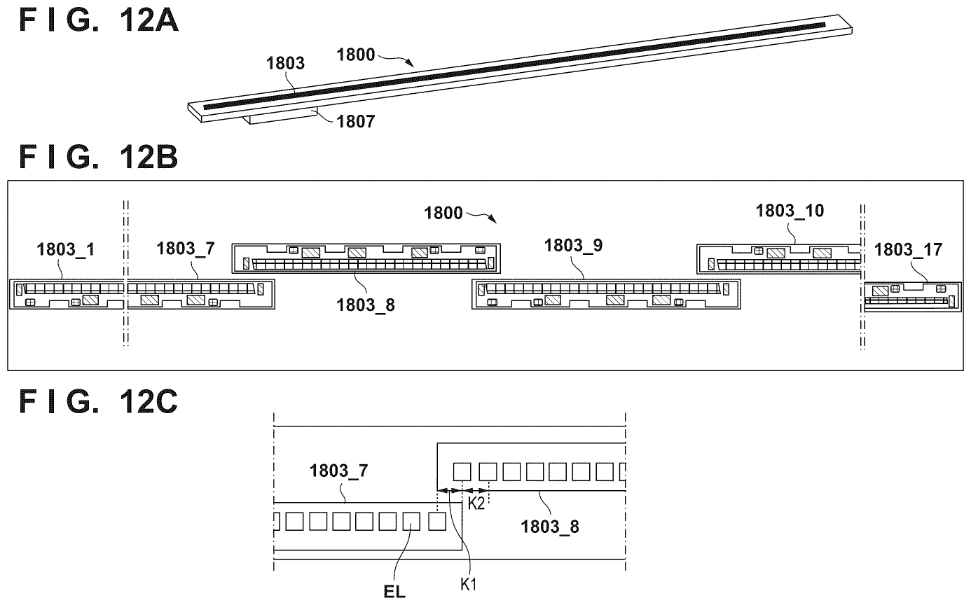

With reference to FIGS. 12A to 12C, the second application example of the light-emitting device 100 will be described. The second application example is an example in which the light-emitting device shown in FIG. 11 is applied to a head substrate 1800 of an exposure head of an image forming apparatus. FIG. 12A is a schematic perspective view of the head substrate 1800. FIG. 12B shows an array of the plurality of light-emitting devices provided on the head substrate 1800. FIG. 12C is an enlarged view of part of FIG. 12B.

LED chips 1803 are mounted on the head substrate 1800. The LED chip 1803 is, for example, the light-emitting device of the first application example shown in FIG. 11.

As shown in FIG. 12A, the LED chips 1803 are provided on one surface of the head substrate 1800, and a long flexible flat cable (FFC) connector 1807 is provided on the other surface. One surface of the head substrate 1800 in this case is the surface (the upper surface or obverse surface) on which the LED chips 1803 are provided. The other surface of the substrate is the surface (the lower surface or reverse surface) opposite to the side where the LED chips 1803 are provided.

The FFC connector 1807 is attached to the other surface (the lower surface or reverse surface) of the head substrate 1800 such that the longitudinal direction of the FFC connector 1807 extends along the longitudinal direction of the head substrate 1800. The long FFC connector 1807 is provided to receive a control signal (drive signal) from a control circuit unit of the main body of the image forming apparatus. The control signal is transferred to each LED chip 1803. The LED chip 1803 is driven (for light emission or turn-off operation) in accordance with the control signal input to the head substrate 1800.

The LED chips 1803 mounted on the head substrate 1800 will be described. As shown in FIGS. 12B and 12C, the plurality of light-emitting devices is arranged on one surface of the head substrate 1800. For example, (17) LED chips 1803-1 to 1803-17 are arrayed. FIG. 12B exemplarily shows the LED chips 1803_1, 1803_7, 1803_8, 1803_9, 1803_10, and 1803_17. In each of the LED chips 1803_1 to 1803_17, the plurality of light-emitting elements EL is arranged in the longitudinal direction, and for example, 516 light-emitting elements EL are arrayed.

An inter-center distance k2 of the adjacent light-emitting devices in the longitudinal direction of the LED chip 1803 corresponds to the resolution of the image forming apparatus. If, for example, the resolution of the image forming apparatus according to the second application example is 1,200 dpi, the plurality of light-emitting devices is arrayed such that the inter-center distance k2 between the adjacent light-emitting devices in the longitudinal direction of the LED chips 1803_1 to 1803_17 is 21.16 μm. Accordingly, the exposure range of the exposure head is about 314 mm.

The photosensitive layer of the photosensitive drum is formed to have a width of 314 mm or more. Since the length of a long side of an A4 size recording sheet and the length of a short side of an A3 size recording sheet are 297 mm, the exposure head according to this embodiment has an exposure range that allows the formation of images on both an A4 size recording sheet and an A3 size recording sheet. Note that FIGS. 12A to 12C show an example in which the plurality of light-emitting devices is arrayed in the longitudinal direction. However, the plurality of light-emitting devices may be arrayed in the transverse direction in addition to the longitudinal direction.

The LED chips 1803_1 to 1803_17 are arrayed in the axial direction of the photosensitive drum. More specifically, the LED chips 1803_1 to 1803_17 are alternately arranged in two lines along the axial direction of the photosensitive drum. That is, as shown in FIG. 12B, the odd-numbered LED chips 1803_1, 1803_3, . . . 1803_17, counted from the left, are mounted in one line in the longitudinal direction of the head substrate 1800. The even-numbered LED chips 1803_2, 1803_4, . . . 1803_16, counted from the left, are mounted in one line in the longitudinal direction of the head substrate 1800. The LED chips 1803 are arranged in this manner.

As shown in FIG. 12C, this makes it possible to equalize an inter-center distance k1 between the light-emitting elements EL with the inter-center distance k2 between the light-emitting elements EL in the longitudinal direction of the LED chip 1803. The inter-center distance k1 between the light-emitting elements EL indicates the inter-center distance between the light-emitting element EL on one end of the LED chip 1803_7 and the light-emitting element EL on the other end of the LED chip 1803_8. The inter-center distance k2 between the light-emitting elements EL indicates the inter-center distance k2 between the adjacent light-emitting elements EL in the LED chip 1803_8.

That is, it is possible to equalize the inter-center distance k1 between the adjacent light-emitting elements EL arranged on one end of the LED chip 1803 and the other end of the other LED chip 1803 with the inter-center distance k2 between the adjacent light-emitting elements EL on one LED chip 1803.

In each LED chip, the light-emitting elements are arranged on a line along the main scanning direction (the axial direction of a photosensitive drum) and are electrically connected in parallel to each other with a power supply wiring provided along the main scanning direction.

If light-emitting devices (LED chips) are used for an exposure head, to perform linear exposure, the light-emitting area 1702 is shaped such that the ratio between the length in the longitudinal direction (first direction X) and the length in the transverse direction (second direction Y) becomes large as compared with a case where light-emitting devices are used for a display apparatus or the like. The substrate of each LED chip is also shaped such that the ratio between the length in the longitudinal direction (first direction X) and the length in the transverse direction (second direction Y) becomes large.

More specifically, for example, the length of a long side of the LED chip (or the light-emitting area 1702) is five or more times or may be 10 or more times the length of a short side of the LED chip (or the light-emitting area 1702). For example, the length of a long side of the LED chip (or the light-emitting area 1702) can be 20 or more times the length of a short side of the LED chip (or the light-emitting area 1702).

The length of a long side of the LED chip is determined by the length of the photosensitive drum 2 in the axial direction, the number of LED chips arranged in the axial direction, and the manner of arranging the LED chips 1803. The length of a short side of the LED chip 1803 is determined by whether the light-emitting elements EL are arranged in the light-emitting area 1702 in a direction perpendicular to the axis of the photosensitive drum and the placements of the pads 1704 and the contact regions 1703.

In addition, the organic layer can be configured to have a light-emitting layer that emits red light in consideration of the wavelength dependence of the photosensitivity of the photosensitive drum 2.

The LED chip 1803 may have a color filter. Having a color filter makes it possible to absorb stray light from unintentional directions without reducing the regular amount of light entering the photosensitive drum, thereby improving the print quality.

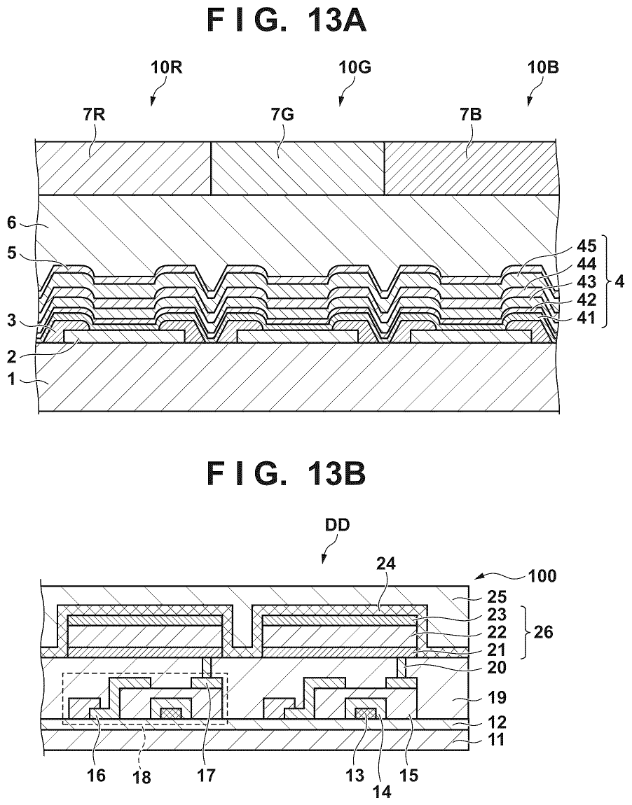

Next, with reference to FIGS. 13A and 13B, the third application example of the light-emitting device 100 will be described. The third application example is an example in which the light-emitting device 100 is applied to a display apparatus. FIGS. 13A and 13B are schematic sectional views showing an example of a display apparatus including an organic light-emitting element and a transistor connected to the organic light-emitting element. The transistor is an example of an active element. The transistor may be a thin-film transistor (TFT).

FIG. 13A shows an example of a pixel that is a constituent element of the display apparatus. The pixel includes sub-pixels 10. One sub-pixel corresponds to one light-emitting element in the light-emitting device 100. The sub-pixels are divided into sub-pixels 10R, 10G, and 10B by emitted light components. The light emission colors may be discriminated by the wavelengths of light components emitted from the light-emitting layers, or light emitted from each sub-pixel may be selectively transmitted or undergo color conversion by a color filter or the like. Each sub-pixel includes a reflective electrode 2 as the first electrode on an interlayer insulating layer 1, an insulating layer 3 covering the end of the reflective electrode 2, an organic compound layer 4 covering the first electrode and the insulating layer, a transparent electrode 5 as the second electrode, a protection layer 6, and a color filter 7.

The interlayer insulating layer 1 can include a transistor and a capacitive element arranged in the interlayer insulating layer 1 or a layer below it. The transistor and the first electrode can electrically be connected via a contact hole (not shown) or the like.

The insulating layer 3 is also called a bank or a pixel isolation film. The insulating layer 3 covers the end of the first electrode, and is arranged to surround the first electrode. A portion where no insulating layer is arranged is in contact with the organic compound layer 4 to form a light-emitting area.

The organic compound layer 4 includes a hole injection layer 41, a hole transport layer 42, a first light-emitting layer 43, a second light-emitting layer 44, and an electron transport layer 45.

The second electrode 5 may be a transparent electrode, a reflective electrode, or a semi-transmissive electrode.

The protection layer 6 suppresses permeation of water into the organic compound layer. The protection layer is shown as a single layer but may include a plurality of layers. Each layer can be an inorganic compound layer or an organic compound layer.

The color filter 7 is divided into color filters 7R, 7G, and 7B by colors. The color filters can be formed on a planarizing film (not shown). A resin protection layer (not shown) may be arranged on the color filters. The color filters can be formed on the protection layer 6. Alternatively, the color filters can be provided on the counter substrate such as a glass substrate, and then the substrate may be bonded.

A display apparatus DD shown in FIG. 13B is provided with an organic light-emitting element 26 and a TFT 18 as an example of a transistor. A substrate 11 of glass, silicon, or the like is provided and an insulating layer 12 is provided on the substrate 11. An active element 18 such as a TFT is arranged on the insulating layer, and a gate electrode 13, a gate insulating film 14, and a semiconductor layer 15 of the active element are arranged. The TFT 18 further includes the semiconductor layer 15, a drain electrode 16, and a source electrode 17. An insulating film 19 is provided on the TFT 18. The source electrode 17 and an anode 21 forming the organic light-emitting element 26 are connected via a contact hole 20 formed in the insulating film.

Note that a method of electrically connecting the electrodes (anode and cathode) included in the organic light-emitting element 26 and the electrodes (source electrode and drain electrode) included in the TFT is not limited to that shown in FIG. 13B. That is, one of the anode and cathode and one of the source electrode and drain electrode of the TFT are electrically connected. The TFT indicates a thin-film transistor.

In the display apparatus DD shown in FIG. 13B, an organic compound layer is illustrated as one layer. However, an organic compound layer 22 may include a plurality of layers. A first protection layer 24 and a second protection layer 25 are provided on a cathode 23 to suppress deterioration of the organic light-emitting element.

A transistor is used as a switching element in the display apparatus DD shown in FIG. 13B, but another switching element may be used instead.

The transistor used in the display apparatus DD shown in FIG. 13B is not limited to a transistor using a single-crystal silicon wafer, and may be a thin-film transistor including an active layer on an insulating surface of a substrate. Examples of the active layer include single-crystal silicon, amorphous silicon, non-single-crystal silicon such as microcrystalline silicon, and a non-single-crystal oxide semiconductor such as indium zinc oxide and indium gallium zinc oxide. Note that a thin-film transistor is also called a TFT element.

The transistor included in the display apparatus DD shown in FIG. 13B may be formed in the substrate such as an Si substrate. Forming the transistor in the substrate means forming the transistor by processing the substrate such as an Si substrate. That is, when the transistor is included in the substrate, it can be considered that the substrate and the transistor are formed integrally.

In this application example, the light emission luminance of the organic light-emitting element can be controlled by the TFT which is an example of a switching element, and the plurality of organic light-emitting elements can be provided in a plane to display an image with the light emission luminances of the respective elements. Note that the switching element according to this embodiment is not limited to the TFT, and may be a transistor formed from low-temperature polysilicon or an active matrix driver formed on the substrate such as an Si substrate. The term “on the substrate” may mean “in the substrate”. Whether to provide a transistor in the substrate or use a TFT is selected based on the size of the display unit. For example, if the size is about 0.5 inch, the organic light-emitting element is preferably provided on the Si substrate.

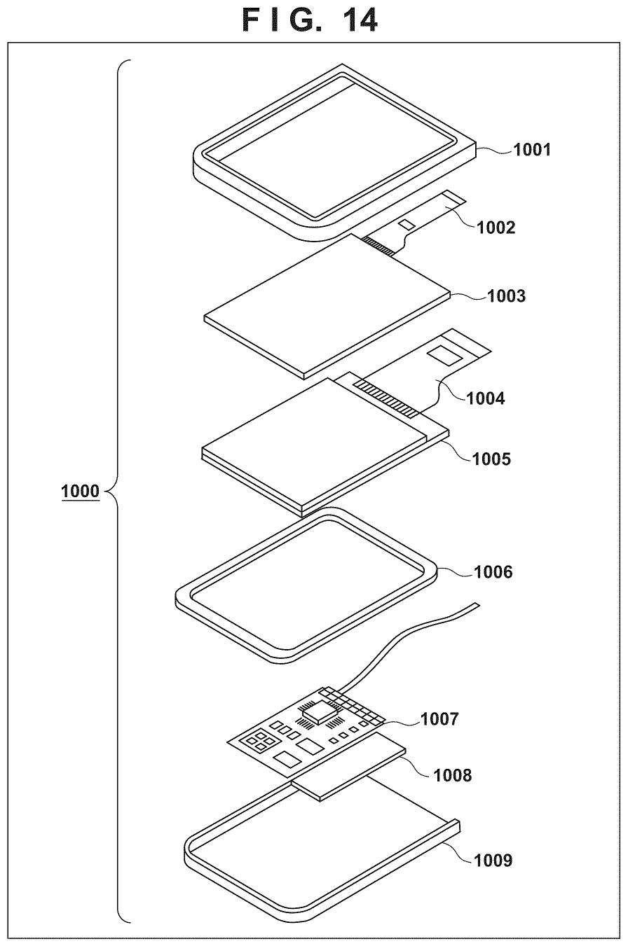

Next, with reference to FIG. 14, the fourth application example of the light-emitting device 100 will be described. The fourth application example is an example in which the light-emitting device 100 is applied to a display apparatus. FIG. 14 is an exploded perspective view of a display apparatus according to the fourth application example. A display apparatus 1000 can include a touch panel 1003, a display panel 1005, a frame 1006, a circuit board 1007, and a battery 1008 between an upper cover 1001 and a lower cover 1009. Flexible printed circuits (FPCs) 1002 and 1004 are respectively connected to the touch panel 1003 and the display panel 1005. Transistors are printed on the circuit board 1007. The battery 1008 is unnecessary if the display apparatus is not portable equipment. Even when the display apparatus is portable equipment, the battery 1008 may be provided at another position.

The display apparatus according to this application example may include color filters of red, green, and blue. The color filters of red, green, and blue may be arranged in a delta array.

The display apparatus according to this application example may be used as a display unit of a portable terminal. At this time, the display unit can have both a display function and an operation function. Examples of the portable terminal are a portable phone such as a smartphone, a tablet, and a head mounted display.

The display apparatus according to this application example can be used for a display unit of an image capturing apparatus including an optical unit having a plurality of lenses, and an image sensor for receiving light having passed through the optical unit. The image capturing apparatus can include a display unit for displaying information acquired by the image sensor. In addition, the display unit can be either a display unit exposed outside the image capturing apparatus, or a display unit arranged in the finder. The image capturing apparatus can be a camera such as a digital camera or a digital video camera.

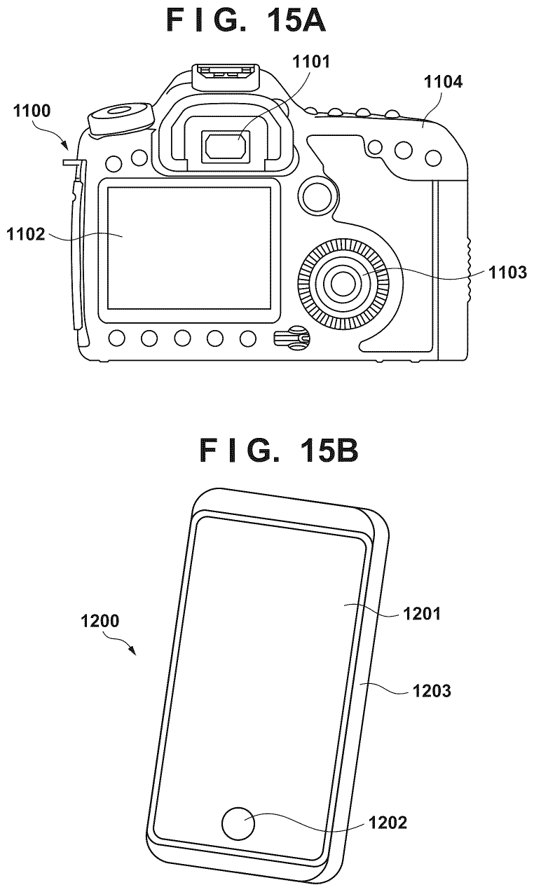

Next, with reference to FIG. 15A, the fifth application example of the light-emitting device 100 will be described. The fifth application example is an example in which the light-emitting device 100 is applied to an image capturing apparatus. FIG. 15A is a schematic view showing an example of an image capturing apparatus according to the fifth application example. An image capturing apparatus 1100 can include a viewfinder 1101, a rear display 1102, an operation unit 1103, and a housing 1104. The viewfinder 1101 can include the display apparatus to which the light-emitting device 100 is applied. In this case, the display apparatus can display not only an image to be captured but also environment information, image capturing instructions, and the like. Examples of the environment information are the intensity and direction of external light, the moving velocity of an object, and the possibility that an object is covered with an obstacle.

The timing suitable for image capturing is a very short time, so the information is preferably displayed as soon as possible. It is therefore preferable to use the display apparatus using the organic light-emitting element having a high response speed.

The image capturing apparatus 1100 includes an optical unit (not shown). This optical unit has a plurality of lenses, and forms an image on an image sensor accommodated in the housing 1104. The focal points of the plurality of lenses can be adjusted by adjusting the relative positions. This operation can also automatically be performed. The image capturing apparatus may be called a photoelectric conversion apparatus. The photoelectric conversion apparatus can include, as an image capturing method, not a method of sequentially capturing images but a method of detecting the difference from a preceding image, a method of extracting an image from an always recorded image, and the like.

Next, with reference to FIG. 15B, the sixth application example of the light-emitting device 100 will be described. The sixth application example is an example in which the light-emitting device 100 is applied to electronic equipment. FIG. 15B is a schematic view showing an example of electronic equipment according to the sixth application example. Electronic equipment 1200 includes a display unit 1201, an operation unit 1202, and a housing 1203. The housing 1203 can accommodate a circuit, a printed board having this circuit, a battery, and a communication unit. The operation unit 1202 can be a button or a touch-panel-type reaction unit. The operation unit can also be a biometric authentication unit that performs unlocking or the like by authenticating the fingerprint. The electronic equipment including the communication unit can also be regarded as a communication equipment. The electronic equipment may also have a camera function by including a lens and an image sensor. An image captured by the camera function is displayed on the display unit. Examples of the electronic equipment are a smartphone and a laptop computer.

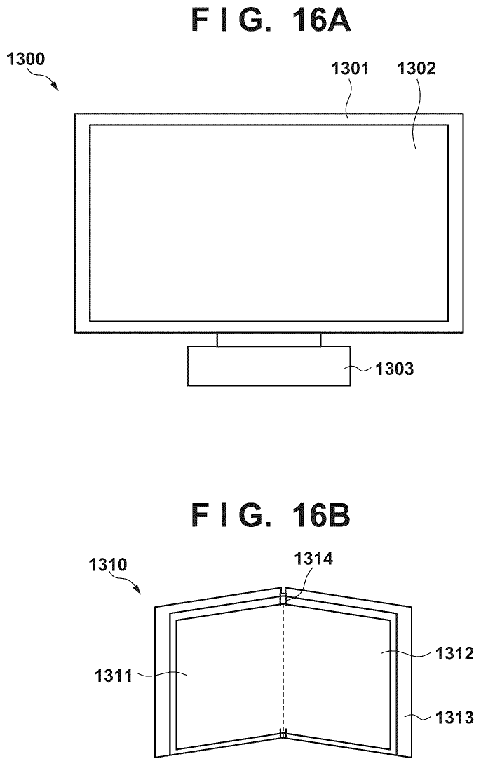

Next, with reference to FIG. 16A, the seventh application example of the light-emitting device 100 will be described. The seventh application example is an example in which the light-emitting device 100 is applied to a display apparatus. FIG. 16A is a view showing an example of a display apparatus 1300 according to the seventh application example. The display apparatus 1300 can be configured as a television monitor, a PC monitor, or the like. A display apparatus 1300 includes a frame 1301 and a display unit 1302. The light-emitting device according to this embodiment can be used for the display unit 1302. The display apparatus 1300 includes a base 1303 that supports the frame 1301 and the display unit 1302. The base 1303 is not limited to the form shown in FIG. 16A. The lower side of the frame 1301 may also function as the base. In addition, the frame 1301 and the display unit 1302 can be bent. The radius of curvature in this case can be 5,000 mm (inclusive) to 6,000 mm (inclusive).

Next, with reference to FIG. 16B, the eighth application example of the light-emitting device 100 will be described. The eighth application example is an example in which the light-emitting device 100 is applied to a display apparatus. FIG. 16B is a view showing an example of a display apparatus 1310 according to the eighth application example. The display apparatus 1310 can be folded, and is a so-called foldable display apparatus. The display apparatus 1310 includes a first display unit 1311, a second display unit 1312, a housing 1313, and a bending point 1314. Each of the first display unit 1311 and the second display unit 1312 may include the light-emitting device according to this embodiment. The first display unit 1311 and the second display unit 1312 can also be one seamless display apparatus. The first display unit 1311 and the second display unit 1312 can be divided by the bending point. The first display unit 1311 and the second display unit 1312 can display different images, and the first and second display units can also display one image together.

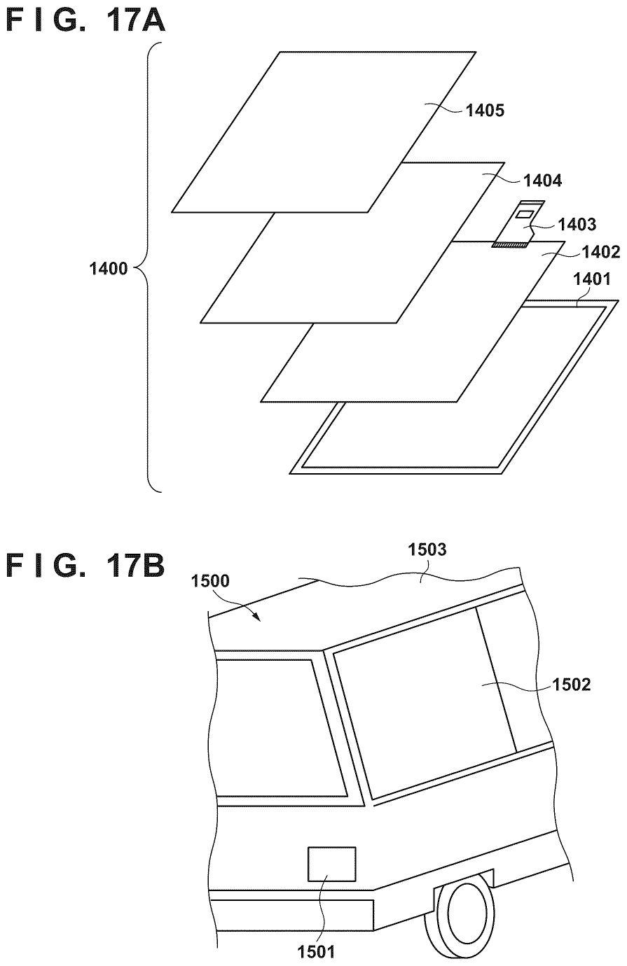

Next, with reference to FIG. 17A, the ninth application example of the light-emitting device 100 will be described. The ninth application example is an example in which the light-emitting device 100 is applied to an illumination apparatus. FIG. 17A is a schematic view showing an example of an illumination apparatus 1400 according to the ninth application example. The illumination apparatus 1400 can include a housing 1401, a light source 1402, a circuit board 1403, an optical film 1404, and a light diffusing unit 1405. The light source may include the light-emitting device 100. The optical filter can be a filter that improves the color rendering of the light source. When performing lighting-up or the like, the light diffusing unit can throw the light of the light source over a broad range by effectively diffusing the light. The optical filter and the light diffusing unit may be provided on the light emission side of illumination. A cover may be provided on the outermost portion, as desired.

The illumination apparatus is, for example, an apparatus for illuminating the interior of the room. The illumination apparatus can emit white light, natural white light, or light of any color from blue to red. The illumination apparatus can also include a light control circuit for controlling these light components. The illumination apparatus can also include the organic light-emitting element according to the present disclosure, and a power supply circuit connected to it. The power supply circuit is a circuit for converting an AC voltage into a DC voltage. White has a color temperature of 4,200 K, and natural white has a color temperature of 5,000 K. The illumination apparatus may include a color filter.

In addition, the illumination apparatus according to this application example may include a heat radiation unit. The heat radiation unit radiates the internal heat of the apparatus to the outside of the apparatus, and examples are a metal having a high specific heat and liquid silicon.

Next, with reference to FIG. 17B, the tenth application example of the light-emitting device 100 will be described. The tenth application example is an example in which the light-emitting device 100 is applied to an automobile as a moving body. FIG. 17B is a schematic view of an automobile that is an example of a moving body according to the tenth application example. The automobile includes a taillight that is an example of a lighting appliance. An automobile 1500 has a taillight 1501, and can have a form in which the taillight is turned on when performing a braking operation or the like.

The taillight 1501 may include the light-emitting device 100. The taillight can include a protection member for protecting an organic EL element. The material of the protection member is not limited as long as the material is a transparent material with a strength that is high to some extent, and the protection member is preferably made of polycarbonate or the like. A furandicarboxylic acid derivative, an acrylonitrile derivative, or the like may be mixed in polycarbonate.

The automobile 1500 can include a vehicle body 1503, and a window 1502 attached to the vehicle body 1503. This window can be a window for checking the front and back of the automobile, and otherwise, can be a transparent display. The transparent display may include a display apparatus to which the light-emitting device 100 is applied. In this case, the constituent materials of the electrodes and the like of the display apparatus are formed by transparent members.

The moving body according to this application example may be a ship, an aircraft, a drone, or the like. The moving body may include a main body and a lighting appliance provided in the main body. The lighting appliance may emit light to show the position of the main body. The light-emitting device 100 can be applied to the lighting appliance.

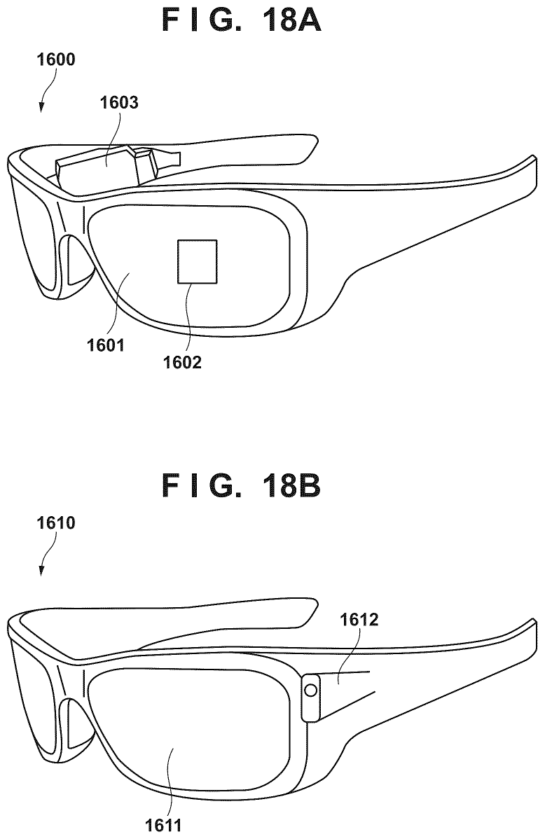

Next, with reference to FIG. 18A, the eleventh application example of the light-emitting device 100 will be described. The eleventh application example is an example in which the light-emitting device 100 is applied to glasses 1600 as an example of a display apparatus. FIG. 18A is a schematic view of the glasses 1600 according to the eleventh application example. The glasses 1600 can be configured as, for example, a device that can be worn as a wearable device such as smartglasses, an HMD, or a smart contact lens. The glasses 1600 include, for example, an image capturing apparatus capable of photoelectrically converting visible light and a display apparatus capable of emitting visible light.

An image capturing apparatus 1602 such as a CMOS sensor or an SPAD is provided on the surface side of a lens 1601 of the glasses 1600. In addition, the display apparatus according to each embodiment described above is provided on the back surface side of the lens 1601.

The glasses 1600 further include a control apparatus 1603. The control apparatus 1603 functions as a power supply that supplies electric power to the image capturing apparatus 1602 and the display apparatus according to each embodiment. In addition, the control apparatus 1603 controls the operations of the image capturing apparatus 1602 and the display apparatus. An optical system configured to condense light to the image capturing apparatus 1602 is formed on the lens 1601.

Next, with reference to FIG. 18B, the twelfth application example of the light-emitting device 100 will be described. The twelfth application example is an example in which the light-emitting device 100 is applied to glasses 1610 as an example of a display apparatus. FIG. 18B is a schematic view of the glasses 1610 according to the twelfth application example. The glasses 1610 can be configured as, for example, a device that can be worn as a wearable device such as smartglasses, an HMD, or a smart contact lens. The glasses 1610 include a control apparatus 1612. An image capturing apparatus corresponding to the image capturing apparatus 1602 and the display apparatus are mounted on the control apparatus 1612. An optical system configured to project light emitted from the display apparatus in the control apparatus 1612 is formed in a lens 1611, and an image is projected to the lens 1611. The control apparatus 1612 functions as a power supply that supplies electric power to the image capturing apparatus and the display apparatus, and controls the operations of the image capturing apparatus and the display apparatus. The control apparatus may include a line-of-sight detection unit that detects the line of sight of a wearer. The detection of a line of sight may be done using infrared rays. An infrared ray emitting unit emits infrared rays to an eyeball of the user who is gazing at a displayed image. An image capturing unit including a light receiving element detects reflected light of the emitted infrared rays from the eyeball, thereby obtaining a captured image of the eyeball. A reduction unit for reducing light from the infrared ray emitting unit to the display unit in a planar view is provided, thereby reducing deterioration of image quality.

The line of sight of the user to the displayed image is detected from the captured image of the eyeball obtained by capturing the infrared rays. An arbitrary known method can be applied to the line-of-sight detection using the captured image of the eyeball. As an example, a line-of-sight detection method based on a Purkinje image obtained by reflection of irradiation light by a cornea can be used.

More specifically, line-of-sight detection processing based on pupil center corneal reflection is performed. Using pupil center corneal reflection, a line-of-sight vector representing the direction (rotation angle) of the eyeball is calculated based on the image of the pupil and the Purkinje image included in the captured image of the eyeball, thereby detecting the line-of-sight of the user.

The display apparatus as an application example of the light-emitting device 100 may include an image capturing apparatus including a light receiving element, and control an image displayed on the display apparatus based on the line-of-sight information of the user from the image capturing apparatus.

More specifically, the display apparatus decides a first display region at which the user is gazing and a second display region other than the first display region based on the line-of-sight information. The first display region and the second display region may be decided by the control apparatus of the display apparatus, or those decided by an external control apparatus may be received. In the display region of the display apparatus, the display resolution of the first display region may be controlled to be higher than the display resolution of the second display region. That is, the resolution of the second display region may be lower than that of the first display region.

In addition, the display region includes a first display region and a second display region different from the first display region, and a region of higher priority is decided from the first display region and the second display region based on line-of-sight information. The first display region and the second display region may be decided by the control apparatus of the display apparatus, or those decided by an external control apparatus may be received. The resolution of the region of higher priority may be controlled to be higher than the resolution of the region other than the region of higher priority. That is, the resolution of the region of relatively low priority may be low.

Note that AI may be used to decide the first display region or the region of higher priority. The AI may be a model configured to estimate the angle of the line of sight and the distance to a target ahead the line of sight from the image of the eyeball using the image of the eyeball and the direction of actual viewing of the eyeball in the image as supervised data. The AI program may be held by the display apparatus, the image capturing apparatus, or an external apparatus. If the external apparatus holds the AI program, it is transmitted to the display apparatus via communication.

When performing display control based on line-of-sight detection, it can suitably be applied to smartglasses further including an image capturing apparatus configured to capture the outside. The smartglasses can display captured outside information in real time.

While the present disclosure has been described with reference to exemplary embodiments, it is to be understood that the present disclosure is not limited to the disclosed exemplary embodiments. The scope of the following claims is to be accorded the broadest interpretation so as to encompass all such modifications and equivalent structures and functions.

This application claims the benefit of priority from Japanese Patent Application No. 2024-093864, filed Jun. 10, 2024, which is hereby incorporated by reference herein in its entirety.

What is claimed is:

1. A light-emitting device comprising:
a light-emitting area including a plurality of light-emitting elements arranged on a surface of a substrate;
a moisture-resistant ring arranged on the surface to surround the light-emitting area; and
an insulating layer covering the light-emitting area and the moisture-resistant ring,
wherein in an orthogonal projection to the surface, the insulating layer has a shape obtained by merging a first portion having a plurality of corners including a first corner and a second portion having a shape with the first corner expanded in an outward direction.

2. The light-emitting device according to claim 1, wherein
the second portion has a round shape.

3. The light-emitting device according to claim 1, wherein
the second portion has a shape with the first corner expanded in a radial direction.

4. The light-emitting device according to claim 1, wherein
the first portion has a polygonal shape.

5. The light-emitting device according to claim 4, wherein
the polygonal shape is a quadrangular shape.

6. The light-emitting device according to claim 1, wherein
the first portion has a shape that is mathematically similar to an outer shape of the moisture-resistant ring.

7. The light-emitting device according to claim 1, wherein
the first portion has a shape that is mathematically similar to a smallest quadrangle that contains the moisture-resistant ring.

8. The light-emitting device according to claim 1, wherein
an interior angle of two sides forming the first corner is one of a right angle, an obtuse angle, and an acute angle.

9. The light-emitting device according to claim 1, wherein
the plurality of corners includes a second corner, and the second portion has a shape with each of the first corner and the second corner expanded in an outward direction.

10. The light-emitting device according to claim 1, wherein
the second portion has a shape with each of the plurality of corners expanded in an outward direction.

11. The light-emitting device according to claim 1, wherein
in the orthogonal projection, an outer edge of the moisture-resistant ring has a shape having a plurality of vertices and a plurality of sides connecting adjacent vertices among the plurality of vertices, and
in the orthogonal projection, a shortest distance from each vertex to an outer edge of the insulating layer is larger than a shortest distance from each side to the outer edge of the insulating layer.

12. The light-emitting device according to claim 1, wherein
an outer shape of the light-emitting area is a polygon, and
an outer shape of the moisture-resistant ring includes a portion along one side of the polygon, and the portion has two first line segments whose distance from the one side is a first distance and a second line segment whose distance from the one side is smaller than the first distance and which is located between the two first line segments.

13. An apparatus comprising a light-emitting device defined in claim 1, and a circuit configured to drive the light-emitting device.

14. A light-emitting device comprising:
a light-emitting area including a plurality of light-emitting elements arranged on a surface of a substrate;
a moisture-resistant ring arranged on the surface to surround the light-emitting area; and
an insulating layer covering the light-emitting area and the moisture-resistant ring,
wherein
the moisture-resistant ring has a first side extending in a first direction, a second side extending in a second direction different from the first direction, and a corner connecting the first side and the second side, and
a shortest distance from the corner to an outer edge of the insulating layer is larger than a shortest distance from the first side to the outer edge of the insulating layer.

15. The light-emitting device according to claim 14, wherein
in an orthogonal projection to the surface, a portion of the outer edge of the insulating layer, which is located outside the corner of the moisture-resistant ring, has a round shape.

16. The light-emitting device according to claim 14, wherein
in an orthogonal projection to the surface, a portion of the outer edge of the insulating layer, which is located outside the corner of the moisture-resistant ring, has a shape partially surrounding the corner.

17. The light-emitting device according to claim 14, wherein
an outer shape of the light-emitting area is a polygon, and
an outer shape of the moisture-resistant ring includes a portion along one side of the polygon, and the portion has two first line segments whose distance from the one side is a first distance and a second line segment whose distance from the one side is smaller than the first distance and which is located between the two first line segments.

18. The light-emitting device according to claim 14, wherein
the outer edge of the insulating layer has a shape obtained by expanding, in an outward direction, a corner in a shape formed by a plurality of sides parallel to a plurality of sides forming an outer shape of the moisture-resistant ring.

19. The light-emitting device according to claim 14, wherein
an interior angle of the corner is one of a right angle, an obtuse angle, and an acute angle.

20. An apparatus comprising a light-emitting device defined in claim 14, and a circuit configured to drive the light-emitting device.
